(19) United States
(12) Patent Application Publication
(10) Pub. No.: US 2026/0114036 A1
(43) Pub. Date: Apr. 23, 2026

(54) COMPLEMENTARY FIELD-EFFECT TRANSISTOR DEVICES WITH SELF-ALIGNED LOCAL INTERCONNECT AND METHODS OF FORMING

(71) Applicant: Taiwan Semiconductor Manufacturing Co., Ltd., Hsinchu (TW)

(72) Inventors: Shih-Jung Ho, Hsinchu (TW); Hsin Yang Hung, New Taipei City (TW); Rui-Fu Chen, Hsinchu (TW); Ku-Feng Yang, Baoshan Township (TW); Szuya Liao, Zhubei (TW)

(21) Appl. No.: 19/048,354

(22) Filed: Feb. 7, 2025

Related U.S. Application Data
(60) Provisional application No. 63/708,993, filed on Oct. 18, 2024.

(51) Int. Cl. H10D 84/85; H10D 30/00; H10D 30/01; H10D 30/43; H10D 62/10; H10D 62/13; H10D 64/01; H10D 64/23; H10D 84/01

(52) U.S. Cl. CPC H10D 84/851; H10D 30/014; H10D 30/0191; H10D 30/43; H10D 30/502; H10D 62/121; H10D 62/151; H10D 64/017; H10D 64/254; H10D 64/256; H10D 84/017; H10D 84/0186; H10D 84/856

(57) ABSTRACT

A source/drain (S/D) contact plug is formed in a complementary FET (CFET) device by: forming an S/D opening that extends through the upper S/D region, through a dielectric plug interposed between the upper and lower S/D regions, and into the lower S/D region, then filling the S/D opening with an electrically conductive material. The dielectric plug is surrounded by a contact etch stop layer (CESL). The CESL ensures that a pre-cleaning process for the S/D opening only removes dielectric material(s) disposed within an area defined by the CESL, thereby limiting the amount of widening in the S/D opening. This helps to prevent void (e.g., empty space) from being formed in the widened portion of the S/D opening, thus reducing the electrical resistance of the S/D contact plug, and preventing electrical short or leakage current between the S/D contact plug and an adjacent conductive feature.

### PRIORITY CLAIM AND CROSS-REFERENCE

This application claims priority to U.S. Provisional Patent Application 63/708,993 , filed Oct. 18, 2024 and entitled “Self-aligned Local Interconnect with Double CESL in CFET MDLI Scheme,” which application is hereby incorporated by reference in its entirety.

### BACKGROUND

Semiconductor devices are used in a variety of electronic applications, such as personal computers, cell phones, digital cameras, and other electronic equipment. Semiconductor devices are typically fabricated by depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

Recently, vertically stacked transistor devices, such as complementary field-effect transistor (CFET) devices, provides a promising new architecture that achieves improved integration density by forming nanostructure field-effect transistors (NSFETs) that are vertically stacked over a substrate. Various aspects of this new architecture need to be studied and improved to achieve better device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a complementary field-effect transistor (CFET) in a three-dimensional view, in accordance with an embodiment.

FIGS. 2, 3A, 3B, 4, 5, 6, 7, 8, 9A, 9B, 10A, 10B, 11A, 11B, 12A, 12B, 13A, 13B, 14A, 14B, 14C, 15A, 15B, and 15C are cross-sectional views of a semiconductor device at various stages of manufacturing, in accordance with an embodiment.

FIGS. 16A, 16B, 17A, 17B, 18A, 18B, 19A, 19B, 20A, 20B, and 20C are cross-sectional views of a semiconductor device at various stages of manufacturing, in accordance with another embodiment.

FIGS. 21A and 21B together illustrate a flow chart of a method of forming a semiconductor device, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Throughout the discussion, unless otherwise specified, the same or similar reference numerals in different figures refer to the same or similar element formed by a same or similar material(s) using the same or similar formation method.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, a source/drain contact plug is formed in a complementary FET (CFET) device to extend vertically through the upper source/drain region to the lower source/drain region. The source/drain contact plug is formed by forming a source/drain opening that extends through the upper source/drain region, through a dielectric plug interposed between the upper source/drain region and the lower source/drain region, and into the lower source/drain region, then filling the source/drain opening with an electrically conductive material. The dielectric plug is surrounded by a contact etch stop layer (CESL). The CESL surrounding the dielectric plug ensures that a pre-cleaning process performed for the source/drain opening can only remove dielectric material(s) disposed within an area defined by the sidewalls of the CESL facing the dielectric plug, thereby limiting the amount of widening in the width of the source/drain opening at the location of the dielectric plug. Therefore, the CESL helps to prevent void (e.g., empty space) from being formed in the widened portion of the source/drain opening, which in turn reduces the electrical resistance of the source/drain contact plug. In addition, the CESL also prevents electrical short or leakage current between the source/drain contact plug and an adjacent conductive feature. As a result, device reliability and production yield are increased, while production cost and power consumption are reduced.

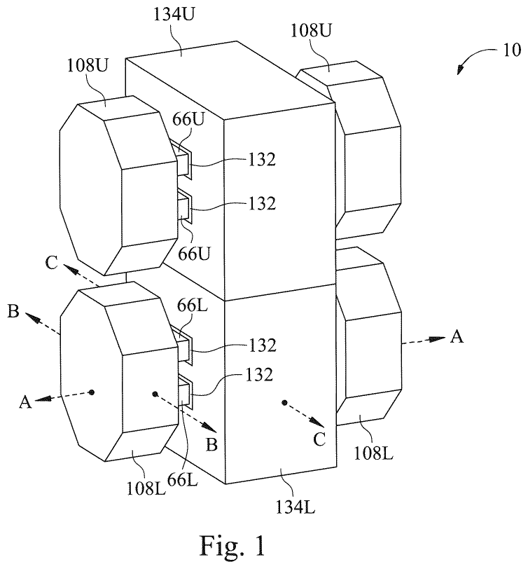

FIG. 1 illustrates an example of a CFET 10, in accordance with an embodiment. FIG. 1 is a three-dimensional view, where some features of the CFET 10 are omitted for illustration clarity. The CFET 10 may be a part of a semiconductor device that includes multiple CFETs.

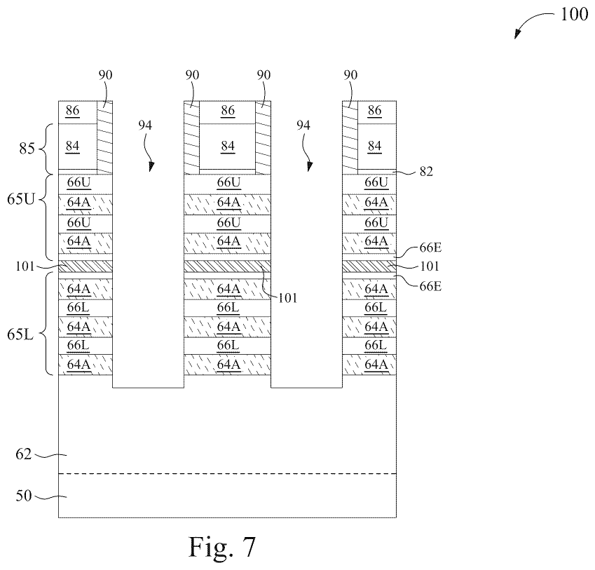

The CFET 10 includes vertically stacked nanostructure field-effect transistors (FETs) (e.g., nanowire FETs, nanosheet FETs, multi bridge channel (MBC) FETs, nanoribbon FETs, gate-all-around (GAA) FETs, or the like). For example, the CFET 10 may include a lower nanostructure FET of a first device type (e.g., n-type/p-type) and an upper nanostructure FET of a second device type (e.g., p-type/n-type) that is opposite the first device type. Specifically, the CFET 10 may include a lower PMOS transistor and an upper NMOS transistor, or the CFET 10 may include a lower NMOS transistor and an upper PMOS transistor. Note that the structure of CFET 10 also allows nanostructure FETs (NSFETs) of the same device type to be vertically stacked to form semiconductor devices. Therefore, the terminology CFET is used herein as a generic term to refer to the vertically stacked nature of the device structure, and is not limited to vertically stacked transistors of opposite device types. Each of the nanostructure FETs include semiconductor nanostructures 66 (e.g., lower semiconductor nanostructures 66L, or upper semiconductor nanostructures 66U), where the semiconductor nanostructures 66 act as channel regions (also referred to as channel layers, semiconductor channels regions, or semiconductor channel layers) for the nanostructure FETs. The semiconductor nanostructures 66 may be nanosheets, nanowires, or the like. The lower semiconductor nanostructures 66L (may also be referred to as lower nanostructures 66L) are for a lower nanostructure FET and the upper semiconductor nanostructures 66U (may also be referred to as upper nanostructures 66U) are for an upper nanostructure FET. Isolation structures (not explicitly illustrated in FIG. 1, see, e.g., 101 in FIG. 7) may be used to separate and electrically isolate the upper semiconductor nanostructures 66U from the lower semiconductor nanostructures 66L. For simplicity, a semiconductor nanostructure may also be referred to as a nanostructure hereinafter.

In FIG. 1, gate dielectric layers 132 are along top surfaces, sidewalls, and bottom surfaces of the semiconductor nanostructures 66.

Gate electrodes 134 (including a lower gate electrode 134L and an upper gate electrode 134U) are over the gate dielectric layers 132 and around the semiconductor nanostructures 66. Source/drain regions 108 (including lower epitaxial source/drain regions 108L and upper epitaxial source/drain regions 108U) are disposed at opposing sides of the gate electrodes 134. Source/drain region(s) 108 may refer to a source or a drain, individually or collectively dependent upon the context. Isolation features may be formed to separate the source/drain regions 108 and/or the gate electrodes 134. For example, the lower gate electrode 134L may optionally be separated from the upper gate electrode 134U by an isolation layer. Alternatively, a lower gate electrode 134L may be electrically coupled to (e.g., directly connected to) an upper gate electrode 134U. Further, the upper epitaxial source/drain regions 108U may be separated from lower epitaxial source/drain regions 108L by one or more dielectric layers. The isolation features between channel regions, gates, and source/drain regions allow for vertically stacked transistors, thereby improving device density. Because of the vertically stacked nature of CFETs, CFETs may also be referred to as stacking transistors or folding transistors.

FIG. 1 further illustrates reference cross-sections that are used in later figures. Cross-section A-A is along a longitudinal axis of the semiconductor nanostructures 66 of a CFET and in a direction of, for example, a current flow between the source/drain regions 108 of the CFET. Cross-section C-C is perpendicular to cross-section A-A and along a longitudinal axis of a gate electrode 134 of the CFET. Cross-section B-B is parallel to the cross-section C-C and through the source/drain regions 108 of the CFET. Subsequent figures may refer to these reference cross-sections for clarity.

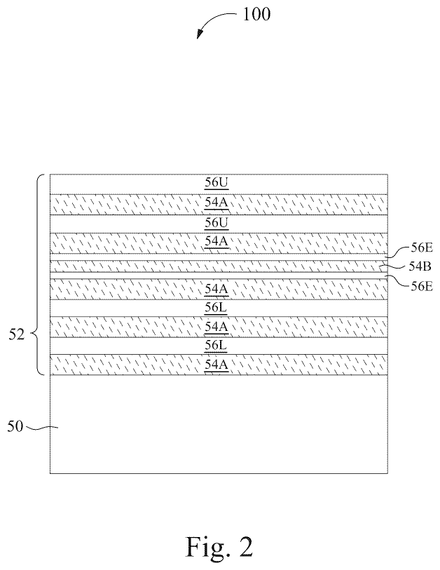

FIGS. 2, 3A, 3B, 4, 5, 6, 7, 8, 9A, 9B, 10A, 10B, 11A, 11B, 12A, 12B, 13A, 13B, 14A, 14B, 14C, 15A, 15B, and 15C are cross-sectional views of a semiconductor device 100 at various stages of manufacturing, in accordance with an embodiment. The semiconductor device 100 is a CFET device. Note that for illustration clarify, not all features of the semiconductor device 100 are illustrated, and the figures may illustrate only a portion of the semiconductor device 100.

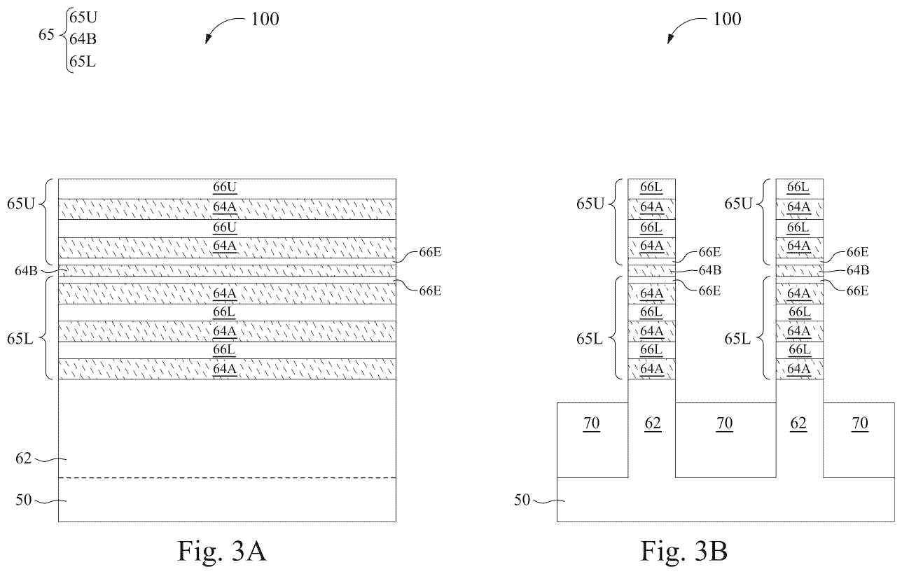

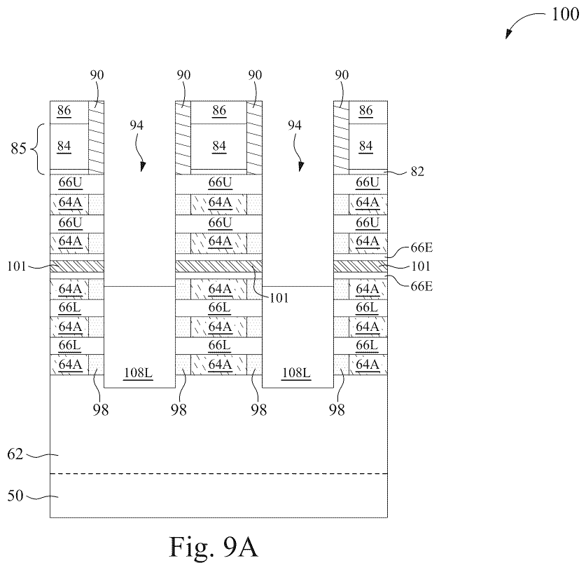

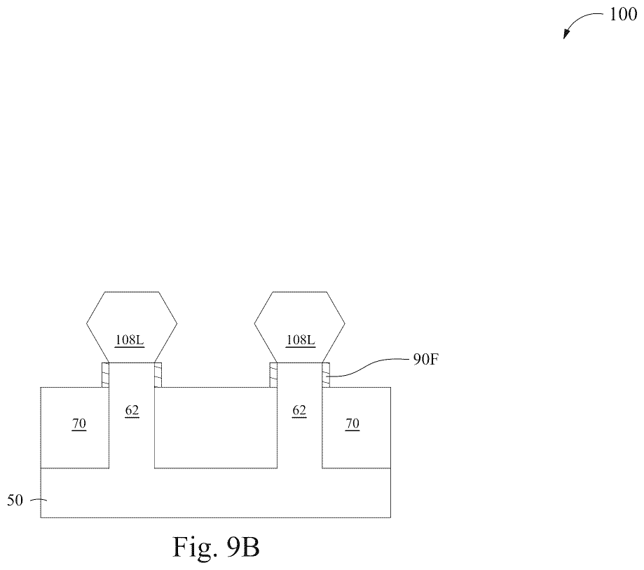

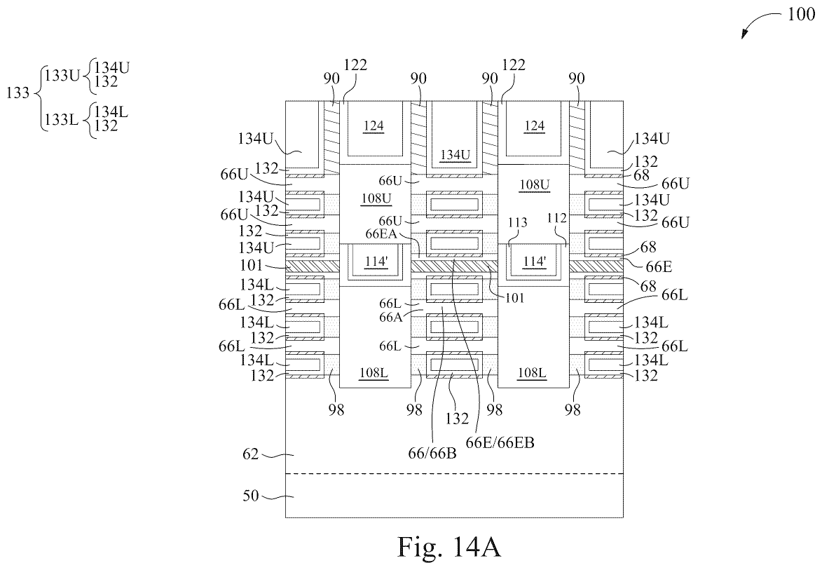

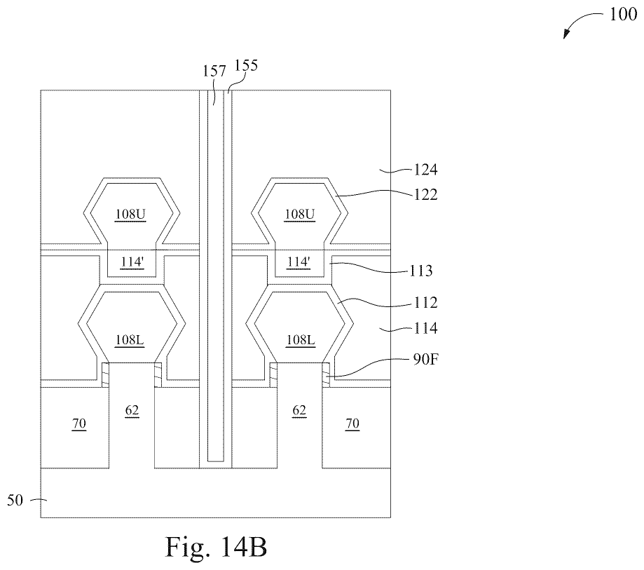

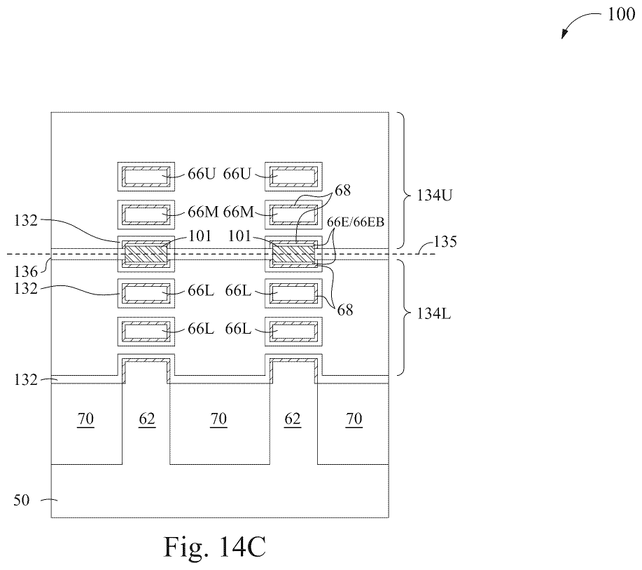

FIGS. 2, 3A, 4, 5, 6, 7, 8, 9A, 10A, 11A, 12A, 13A, 14A, and 15A illustrate cross-sectional views along cross-section A-A of FIG. 1. FIGS. 9B, 10B, 11B, 12B, 13B, 14B and 15B illustrate cross-sectional views along cross-section B-B of FIG. 1. FIGS. 3B, 14C, and 15C illustrate cross-sectional views along cross-section C-C of FIG. 1. Throughout the discussion herein, figures with the same numeral but different alphabets (e.g., FIGS. 14A, 14B, and 14C) illustrate different views (e.g., along different cross-sections) of the same semiconductor device at the same stage of processing.

In FIG. 2, a substrate 50 is provided, and a multi-layer stack 52 is formed over the substrate 50. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including carbon-doped silicon, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The multi-layer stack 52 is formed over the substrate 50. The multi-layer stack 52 includes dummy layers 54 (including first dummy layers 54A and a second dummy layer 54B) and semiconductor layers 56 (including lower semiconductor layers 56L and upper semiconductor layers 56U). The lower semiconductor layers 56L and a subset of the first dummy layers 54A are disposed below the second dummy layer 54B, and are interleaved with each other (e.g., forming an alternating layer pattern). The upper semiconductor layers 56U and another subset of the first dummy layers 54A are disposed above the second dummy layer 54B, and are interleaved with each other.

In the example of FIG. 2, the multi-layer stack 52 further includes etch stop layers (ESLs) 56E formed above and below the second dummy layer 54B. In other words, the second dummy layer 54B is sandwiched between the etch stop layers 56E. In some embodiments, the etch stop layers 56E are formed of a same material as the semiconductor layers 56 using the same or similar formation method. In the illustrated embodiments, the etch stop layers 56E are formed to be thinner than the dummy layers 54 and the semiconductor layers 56. For example, the etch stop layers 56E may have a thickness that is 30%, 20%, 10%, or less, of the thickness of the dummy layers 54 (or the semiconductor layers 56).

As subsequently described in greater detail, the dummy layers 54 will be removed and the semiconductor layers 56 will be patterned to form channel regions of CFETs. For example, the lower semiconductor layers 56L will be patterned to form channel regions of the lower nanostructure FETs of the CFETs, and the upper semiconductor layers 56U will be patterned to form channel regions of the upper nanostructure FETs of the CFETs.

The number of the dummy layers 54 and the number of the semiconductor layers 56 illustrated in FIG. 2 are merely non-limiting examples. It should be appreciated that the multi-layer stack 52 may include any number of the dummy layers 54 and the semiconductor layers 56. Each layer of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like.

The first dummy layers 54A are formed of a first semiconductor material, and the second dummy layer 54B is formed of a second semiconductor material. The first and second semiconductor materials may be selected from the candidate semiconductor materials of the substrate 50. The semiconductor materials of the first dummy layers 54A and the second dummy layer 54B will be subsequently described in greater detail. The first and second semiconductor materials have a high etching selectivity to one another. In some embodiments, the first and second semiconductor materials are compound materials having the same types of atoms but different atomic percentages for the atoms (e.g., silicon germanium with different germanium concentrations). As such, the material of the second dummy layer 54B may be removed at a faster rate than the material of the first dummy layers 54A in subsequent processing.

The semiconductor layers 56 (including the lower semiconductor layers 56L and upper semiconductor layers 56U) are formed of one or more semiconductor material(s). The semiconductor material(s) may be selected from the candidate semiconductor materials of the substrate 50. In some embodiments, the semiconductor layers 56 is formed of a group IV-V material or a group III-V material. The lower semiconductor layers 56L and the upper semiconductor layers 56U may be formed of the same semiconductor material, or may be formed of different semiconductor materials. In some embodiments, the lower semiconductor layers 56L and the upper semiconductor layers 56U are both formed of a semiconductor material suitable for p-type devices and n-type devices, such as silicon. In some embodiments, the lower semiconductor layers 56L are formed of a semiconductor material suitable for p-type devices, such as germanium or silicon-germanium, and the upper semiconductor layers 56U are formed of a semiconductor material suitable for n-type devices, such as silicon or carbon-doped silicon. The semiconductor material(s) of the semiconductor layers 56 will be subsequently described in greater detail. The semiconductor material(s) of the semiconductor layers 56 have a high etching selectivity to the semiconductor materials of the dummy layers 54. As such, the materials of the dummy layers 54 may be removed at a faster rate than the material of the semiconductor layers 56 in subsequent processing.

Some layers of the multi-layer stack 52 may be thicker than other layers of the multi-layer stack 52. The thickness of the second dummy layer 54B may be different from (e.g., greater or less than) the thickness of each of the first dummy layers 54A. In some embodiments, the second dummy layer 54B has a large thickness, such as a greater thickness than each of the first dummy layers 54A. Forming the second dummy layer 54B to a large thickness allows the second dummy layer 54B to be more easily removed in subsequently processing. Additionally, the thickness of each of the semiconductor layers 56 may be different from (e.g., greater or less than) the thickness(es) of each of the first dummy layers 54A and/or the second dummy layer 54B. In some embodiments, each of the semiconductor layers 56 may be thicker than each of the dummy layers 54.

In some embodiments, the first dummy layers 54A are formed of silicon-germanium with a first germanium atomic percentage, the second dummy layer 54B is formed of silicon-germanium with a second germanium atomic percentage that is higher than the first germanium atomic percentage. The difference between the second germanium atomic percentage and the first germanium atomic percentage may be higher than, e.g., about 10 percent or 30 percent, and may be in the range between about 30 percent and about 70 percent. The higher germanium atomic percentage allows the second dummy layer 54B to be etched at a faster rate than the first dummy layers 54A, and allow the second dummy layer 54B to be completed removed during a subsequent etching process, as discussed hereinafter.

Next, in FIGS. 3A and 3B, fins 62 are formed in the substrate 50 and nanostructures 64 (including first dummy nanostructures 64A and second dummy nanostructures 64B) and 66 (including lower semiconductor nanostructures 66L and upper semiconductor nanostructures 66U) are formed in the multi-layer stack 52. The fins 62 may also be referred to as fin bases, base portions, or protrusions. The number of fins 62 illustrated is illustrative and non-limiting. In some embodiments, the nanostructures 64, 66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64, 66 by etching the multi-layer stack 52 may define the first dummy nanostructures 64A from the first dummy layers 54A, the second dummy nanostructures 64B from the second dummy layer 54B, the lower semiconductor nanostructures 66L from the lower semiconductor layers 56L, and the upper semiconductor nanostructures 66U from the upper semiconductor layers 56U. The ESLs 56E of the multi-layer stack 52 are patterned to form nanostructures 65E (may also be referred to as ESLs 65E) by the anisotropic etching performed to form the nanostructures 64 and 66, in some embodiments.

The first dummy nanostructures 64A and the second dummy nanostructures 64B may be collectively referred to as the dummy nanostructures 64. The lower semiconductor nanostructures 66L and the upper semiconductor nanostructures 66U may further be collectively referred to as the semiconductor nanostructures 66. The nanostructures (e.g., 64A, 66L, and 66E) below the second dummy nanostructures 64B may be collectively referred to as lower nanostructures 65L, and the nanostructures (e.g., 64A, 66U, and 66E) above the second dummy nanostructures 64B may be collectively referred to as upper nanostructures 65U. The lower nanostructures 65L, the second dummy nanostructures 64B, and the upper nanostructures 65U may be collectively referred to as nanostructures 65. In the example of FIGS. 3A and 3B, each of the second dummy nanostructures 64B is interposed between a lower nanostructure 65L and an upper nanostructure 65U.

As subsequently described in greater detail, the dummy nanostructures 64 will be removed to form channel regions of CFETs. Specifically, the lower nanostructures 66L will act as channel regions for lower nanostructure FETs of the CFETs. Additionally, the upper nanostructures 66U will act as channel regions for upper nanostructure FETs of the CFETs. The second dummy nanostructures 64B will be subsequently replaced with isolation structures. The isolation structures may define boundaries of the lower nanostructure FETs and the upper nanostructure FETs of the CFETs.

The fins 62 and the nanostructures 64, 66 may be patterned by any suitable method. For example, the fins 62 and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64, 66. In some embodiments, a mask (or other layer) may remain on the nanostructures 64, 66.

In FIGS. 3A and 3B, isolation regions 70 are formed adjacent to the fins 62. The isolation regions 70 may be formed by depositing an insulating material over the substrate 50, the fins 62, and nanostructures 64, 66, and between adjacent fins 62. The insulating material may be an oxide, such as silicon oxide, a nitride, the like, or a combination thereof, and may be formed by high-density plasma chemical vapor deposition (HDP-CVD), flowable chemical vapor deposition (FCVD), the like, or a combination thereof. Other insulating materials formed by any acceptable process may be used. In some embodiments, the insulating material is silicon oxide formed by an FCVD process. An anneal process may be performed after the insulating material is formed. In an embodiment, the insulating material is formed such that excess insulating material covers the nanostructures 64, 66. Although the insulating material is illustrated as a single layer, some embodiments may utilize multiple layers. For example, in some embodiments a liner (not separately illustrated) may first be formed along a surface of the substrate 50, the fins 62, and the nanostructures 64, 66. Thereafter, a fill material, such as one of the previously described insulating materials may be formed over the liner.

A removal process is then applied to the insulating material to remove excess insulating material over the nanostructures 64, 66. In some embodiments, a planarization process such as a chemical mechanical polish (CMP), an etch-back process, combinations thereof, or the like may be utilized. The planarization process exposes the nanostructures 64, 66 such that top surfaces of the nanostructures 64, 66 and the insulating material are level after the planarization process is complete.

The insulating material is then recessed to form the isolation regions 70. The insulating material is recessed such that upper portions of the fins 62 protrude from between neighboring isolation regions 70. Further, the top surfaces of the isolation regions 70 may have a flat surface as illustrated, a convex surface, a concave surface (such as dishing), or a combination thereof. The top surfaces of the isolation regions 70 may be formed flat, convex, and/or concave by an appropriate etch. The isolation regions 70 may be recessed using an etching process, such as one that is selective to the insulating material (e.g., etches the insulating material at a faster rate than the materials of the fins 62 and the nanostructures 64, 66). For example, an etching process using dilute hydrofluoric (dHF) acid may be performed to recess the isolation regions 70.

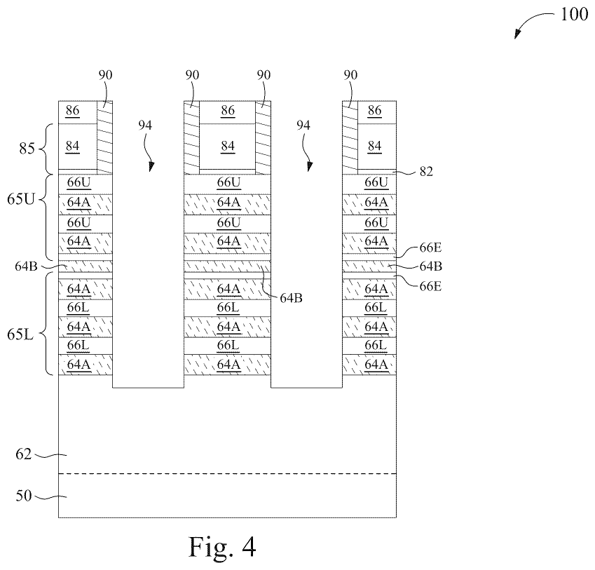

Next, in FIG. 4, a dummy dielectric layer 82 is formed on the fins 62 and/or the nanostructures 64, 66. The dummy dielectric layer 82 may be, for example, silicon oxide, silicon nitride, a combination thereof, or the like, and may be deposited or thermally grown according to acceptable techniques. A dummy gate layer 84 is formed over the dummy dielectric layer 82, and a mask layer 86 is formed over the dummy gate layer 84. The dummy gate layer 84 may be deposited over the dummy dielectric layer 82 and then planarized, such as by a CMP. The mask layer 86 may be deposited over the dummy gate layer 84. The dummy gate layer 84 may be an electrically conductive or non-electrically conductive material and may be selected from a group including amorphous silicon, polycrystalline-silicon (polysilicon), poly-crystalline silicon-germanium (poly-SiGe), or the like. The dummy gate layer 84 may be deposited by physical vapor deposition (PVD), CVD, sputter deposition, or other techniques for depositing the selected material. The dummy gate layer 84 may be formed of other materials that have a high etching selectivity to insulating materials. The mask layer 86 may include, for example, silicon nitride, silicon oxynitride, or the like. In some embodiments, the dummy dielectric layer 82 covers the isolation regions 70, such that the dummy dielectric layer 82 extends between the dummy gate layer 84 and the isolation regions 70. In another embodiments, the dummy dielectric layer 82 covers only the fins 62 and/or the nanostructures 64, 66.

Next, the mask layer 86 is patterned using acceptable photolithography and etching techniques to form masks 86. The pattern of the masks 86 is then transferred to the dummy gate layer 84 and to the dummy dielectric layer 82 to form dummy gates 84 and dummy dielectrics 82, respectively. The dummy gates 84 and the dummy dielectrics 82 are collectively referred to as dummy gate structures 85. The dummy gates 84 cover respective channel regions of the nanostructures 66. The pattern of the masks 86 may be used to physically separate each of the dummy gates 84 from adjacent dummy gates 84. The dummy gates 84 may also have a lengthwise direction substantially perpendicular to the lengthwise direction of respective fins 62. The masks 86 can optionally be removed after patterning, such as by any acceptable etching technique.

Next, gate spacers 90 are formed over the nanostructures 64, 66 and on exposed sidewalls of the masks 86 (if present), the dummy gates 84, and the dummy dielectrics 82. The gate spacers 90 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as CVD, ALD, or the like. Other dielectric materials formed by any acceptable process may be used. Any acceptable etch process, such as a dry etch, may be performed to pattern the dielectric material(s). The etching may be anisotropic. The dielectric material(s), when etched, have portions left on the sidewalls of the dummy gate structures 85 (thus forming the gate spacers 90). Fin spacers 90F (see, e.g., FIG. 9B) may also be formed along sidewalls of the fins 62 as part of forming the gate spacers 90.

Next, source/drain recesses 94 (also referred to as source/drain openings) are formed in the nanostructures 64, 66, and the fins 62. Epitaxial source/drain regions will be subsequently formed in the source/drain recesses 94. The source/drain recesses 94 may extend through the nanostructures 64, 66 and into the fins 62. The fins 62 may be etched such that bottom surfaces of the source/drain recesses 94 are disposed above, below, or level with the top surfaces of the isolation regions 70. The source/drain recesses 94 may be formed by etching the nanostructures 64, 66, and the fins 62 using anisotropic etching processes, such as RIE, NBE, or the like. The gate spacers 90 and the dummy gate structures 85 mask portions of the nanostructures 64, 66, and the fins 62 during the etching processes used to form the source/drain recesses 94. A single etch process or multiple etch processes may be used to etch each layer of the nanostructures 64, 66, and the fins 62. Timed etch processes may be used to stop the etching of the source/drain recesses 94 after the source/drain recesses 94 reach a desired depth.

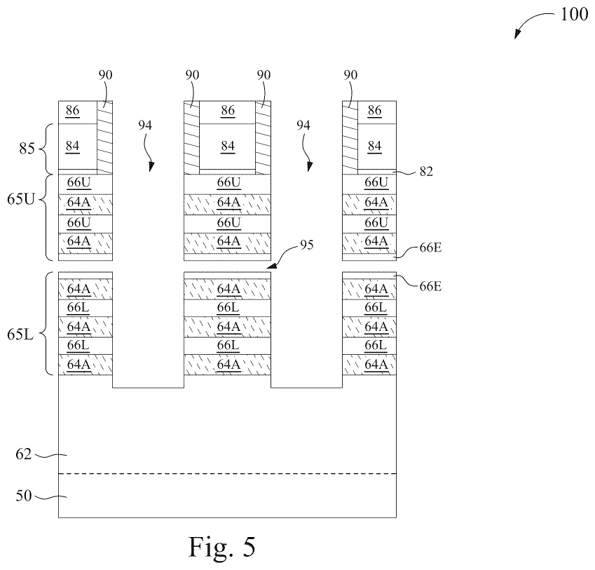

Next, as illustrated by FIG. 5, the second dummy nanostructures 64B in the nanostructures 65 are removed. In some embodiments, a selectively etching process is performed using an etchant selective to (e.g., having a higher etching rate for) the material of the second dummy nanostructures 64B, such that the second dummy nanostructures 64B are completely removed without substantially attacking other materials of the semiconductor device 100. The selective etching process is an isotropic etching process, in an example embodiment. In some embodiments where the second dummy nanostructures 64B are formed of germanium or silicon germanium with a high germanium atomic percentage, the first dummy nanostructures 64A are formed of silicon germanium with a low germanium atomic percentage, and the semiconductor nanostructures 66 are formed of silicon, the selective etching process may comprise a dry etch process using chlorine gas, with or without a plasma. Because the dummy gate structures 85 warp around sidewalls of the nanostructures 66 and 64, the dummy gate structures 85 may support the upper nanostructures 65U so that the upper nanostructures 65U do not collapse upon removal of the second dummy nanostructures 64B. After the removal of the second dummy nanostructures 64B, gaps 95 (e.g., empty spaces) are formed between the upper nanostructures 65U and lower nanostructures 65L.

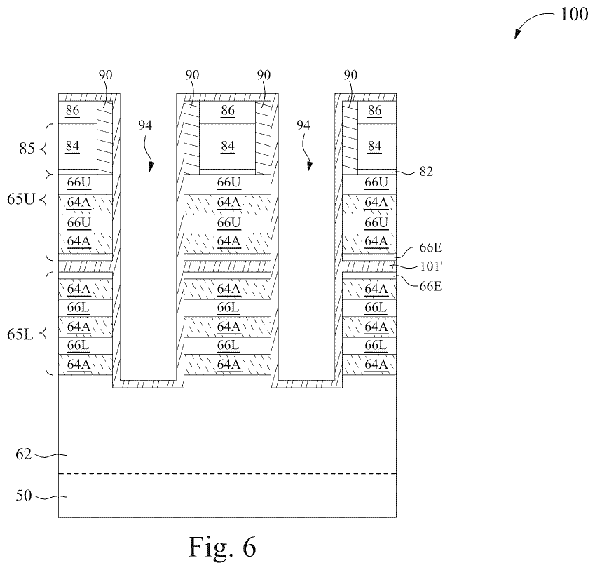

Next, in FIG. 6, a dielectric material 101′ is formed (e.g., conformally) to line the bottoms and sidewalls of the source/drain recesses 94, and to fill the gaps 95 between the nanostructures 66E. In some embodiments, the dielectric material 101′ is a suitable dielectric material such as silicon oxide, silicon nitride, silicon oxynitride, silicon carbonitride, silicon oxycarbide, aluminum oxide, hufnium oxide, zirconium oxide, the like, combinations thereof, or multiplayers thereof. The dielectric material 101′ may be a single layer material, or may comprise a plurality of sub-layers, such as having a bi-layered structure, or a tri-layered structure. A suitable formation method, such as CVD, PVD, ALD, or the like, may be performed to form the dielectric material 101′.

Next, in FIG. 7, an etching process is performed to remove portions of the dielectric material 101′ that are disposed outside of the gaps 95. The etching process may be anisotropic (e.g., an anisotropic plasma etching process), although a suitable isotropic etching process may also be used. After the etching process, remaining portions of the dielectric material 101′ inside the gaps 95 form isolation structures 101 (also referred to as dielectric isolation structures).

In the example of FIG. 7, sidewalls of the isolation structures 101 are straight and are flush with respective sidewalls of the nanostructures 65U and 65L. In other embodiments, the sidewalls of the isolation structures 101 may be curved (e.g., concave, or convex), and/or may not align with (e.g., may protrude from, or be recessed from) the respective sidewalls of the nanostructures 65U and 65L. These and other variations are fully intended to be included within the scope of the present disclosure.

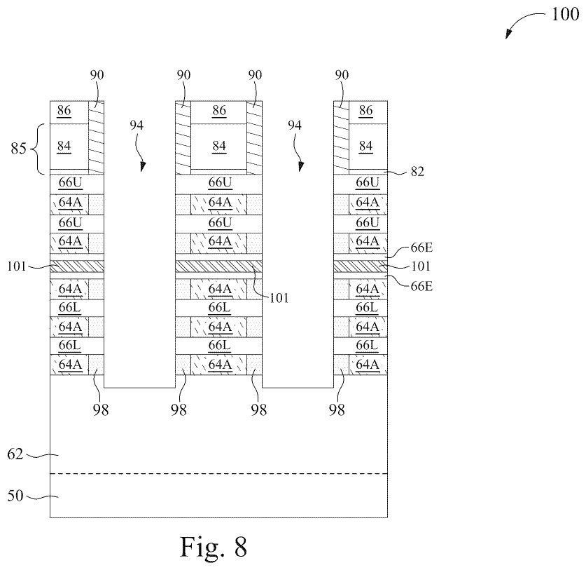

Next, in FIG. 8, inner spacers 98 are formed. Forming the inner spacers 98 may include performing an etching process that laterally etches the first dummy nanostructures 64A to form sidewall recesses in the first dummy nanostructures 64A. The etching process may be isotropic and may be selective to the material of the first dummy nanostructures 64A, so that the first dummy nanostructures 64A are etched at a faster rate than the nanostructures 66. Although sidewalls of the first dummy nanostructures 64A are illustrated as being straight after the etching, the sidewalls may be concave or convex.

The inner spacers 98 are formed in the sidewall recesses, e.g., on sidewalls of the recessed first dummy nanostructures 64A. As subsequently described in greater detail, source/drain regions will be subsequently formed in the source/drain recesses 94, and the first dummy nanostructures 64A will be replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etching processes, such as the etching processes used to form gate structures. Isolation structures 101, on the other hand, are used to isolate the upper semiconductor nanostructures 66U from the lower semiconductor nanostructures 66L. Further, the isolation structures 101 may define the boundaries of the lower nanostructure FETs and the upper nanostructure FETs.

The inner spacers 98 may be formed by conformally depositing an insulating material in the source/drain recesses 94, and on sidewalls of the recessed first dummy nanostructures 64A, and then etching the insulating material. The insulating material may be a hard dielectric material, e.g., a carbon-containing dielectric material such as silicon oxycarbonitride, silicon oxycarbide, or the like. The insulating material may be formed by a deposition process, such as ALD, CVD, or the like. The etching of the insulating material may be anisotropic or isotropic. The insulating material, when etched, has portions remaining along the sidewalls of the (recessed) first dummy nanostructures 64A (thus forming the inner spacers 98). The sidewalls of the inner spacers 98 may be flush with respective sidewalls of the nanostructures 66, or may protrude from or be recessed from the sidewalls of the nanostructures 66.

Next, in FIGS. 9A and 9B, lower epitaxial source/drain regions 108L are formed at the bottoms of the source/drain recesses 94. As illustrated in FIG. 9A, the lower epitaxial source/drain regions 108L are in contact with the lower semiconductor nanostructures 66L and are not in contact with the upper semiconductor nanostructures 66U. Inner spacers 98 electrically insulate the lower epitaxial source/drain regions 108L from the first dummy nanostructures 64A, which will be replaced with replacement gates in subsequent processing.

In some embodiments, the lower epitaxial source/drain regions 108L are epitaxially grown (e.g., from exposed sidewalls of the lower semiconductor nanostructures 66L), and have a conductivity type (e.g., n-type or p-type) that is suitable for the device type (p-type or n-type) of the lower nanostructure FETs. When lower epitaxial source/drain regions 108L are n-type source/drain regions, the respective material may include silicon or carbon-doped silicon, which is doped with an n-type dopant such as phosphorous, arsenic, or the like. When lower epitaxial source/drain regions 108L are p-type source/drain regions, the respective material may include silicon or silicon germanium, which is doped with a p-type dopant such as boron, indium, or the like. The lower epitaxial source/drain regions 108L may be in-situ doped, and may be, or may not be, implanted with the corresponding p-type or n-type dopants. During the epitaxy of the lower epitaxial source/drain regions 108L, the upper semiconductor nanostructures 66U may be masked to prevent unintentional epitaxial growth on the upper semiconductor nanostructures 66U. After the lower epitaxial source/drain regions 108L (also referred to as lower source/drain regions 108L) are grown, the masks on the upper semiconductor nanostructures 66U may then be removed.

As a result of the epitaxy processes used for forming the lower epitaxial source/drain regions 108L, upper surfaces of the lower epitaxial source/drain regions 108L have facets which expand laterally outward beyond sidewalls of the nanostructures 64 and 66. In some embodiments, adjacent lower epitaxial source/drain regions 108L remain separated (see, e.g., FIG. 9B) after the epitaxy process is completed. In other embodiments, these facets cause neighboring lower epitaxial source/drain regions 108L to merge.

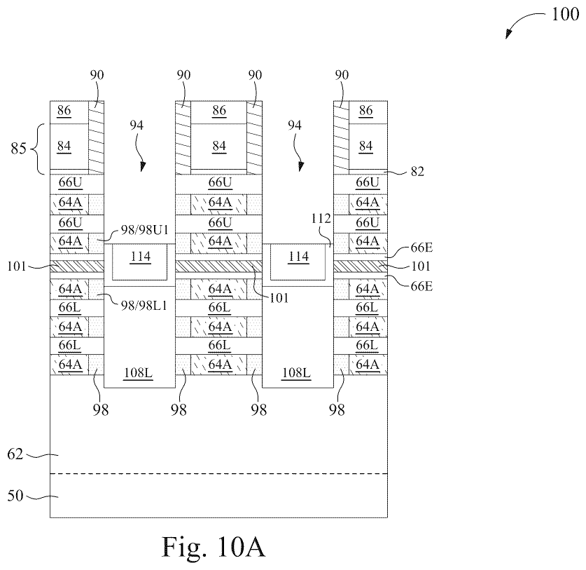

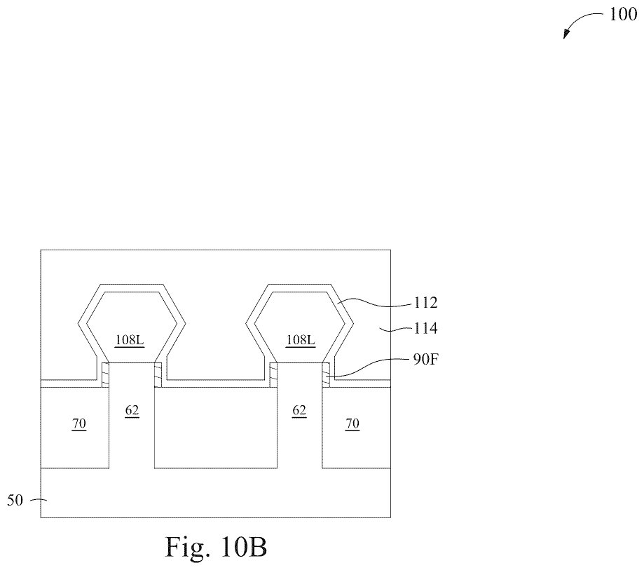

Next, in FIGS. 10A and 10B, a first contact etch stop layer (CESL) 112 and a first interlayer dielectric (ILD) 114 are formed over the lower epitaxial source/drain regions 108L. The first CESL 112 may be formed of a dielectric material having a high etching selectivity from the etching of the first ILD 114, such as silicon nitride, a metal oxide (e.g., an oxide of Hf, Ti, Al, W, Nb, or Re), a metal nitride (e.g., a nitride of Hf, Ti, Al, W, Nb, or Re), or the like, which may be formed by any suitable deposition process, such as CVD, ALD, or the like. The first ILD 114 may be formed of a dielectric material, which may be deposited by any suitable method, such as CVD, plasma-enhanced CVD (PECVD), or FCVD. The applicable dielectric material of the first ILD 114 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 114, followed by a planarization process and then an etch-back process. In some embodiments, the first ILD 114 is etched first, leaving the first CESL 112 unetched. Another etching process is then performed to remove the portions of the first CESL 112 higher than the recessed first ILD 114. After the recessing, the sidewalls of the upper semiconductor nanostructures 66U are exposed. The first ILD 114 and the first CESL 112 in FIGS. 10A and 10B after the recessing may be collectively referred to as dielectric structures 115′.

In the example of FIG. 10A, the dielectric structures 115′ extend along sidewalls of the isolation structures 101, along sidewalls of inner spacers 98U1 (e.g., inner spacers 98 over and closest to the isolation structures 101), and along sidewalls of the inner spacers 98L1 (e.g., inner spacers 98 below and closest to the isolation structures 101). Along the vertical direction of FIG. 10A, each dielectric structure 115′ is disposed below the upper surface of the inner spacer 98U1 and above the lower surface of the inner spacer 98L1, such that the dielectric structure 115′ does not block sidewalls of the nanostructures 66 for electrical connection with source/drain regions.

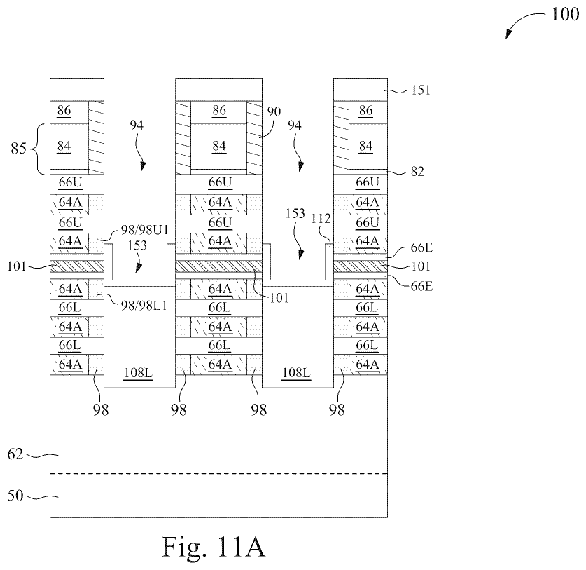

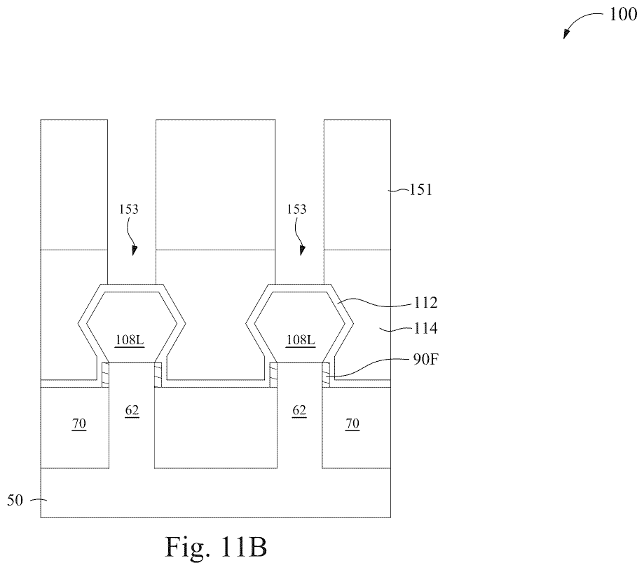

Next, in FIGS. 11A and 11B, portions of the first ILD 114 are removed to form openings 153 in the first ILD 114 over (e.g., directly over) the lower source/drain regions 108L. In the example of FIGS. 11A and 11B, the openings 153 expose portions of the first CESL 112 extending along top surfaces of the lower source/drain regions 108L. As illustrated in FIG. 11A, the openings 153 are disposed under respective source/drain openings 94.

In some embodiments, to form the openings 153, a patterned mask layer 151, such as a patterned photoresist layer, is formed over the dummy gate structures 85, the gate spacers 90, and the dielectric structures 115′. Patterns (e.g., openings) in the patterned mask layer 181 correspond to (e.g., directly overly) the portions of the first ILD 114 to be removed. Next, a suitable etching process, such as an anisotropic etching process performed using an etchant selective to the first ILD 114, is performed to remove the portions of the first ILD 114 and to form the openings 153. After the openings 153 are formed, a suitable removal process, such as ashing, may be performed to remove the patterned mask layer 151.

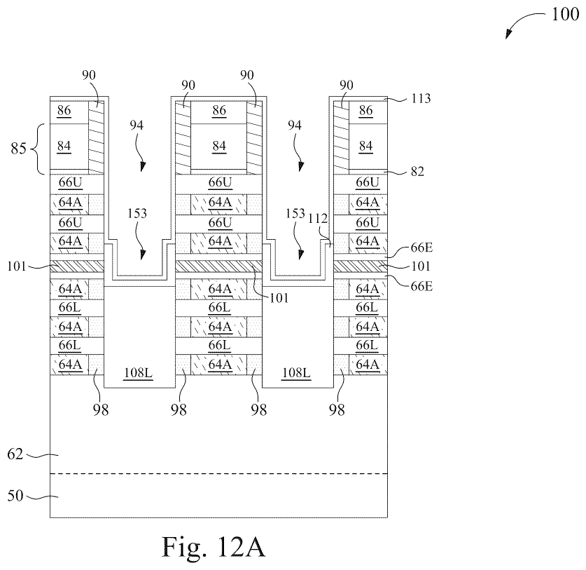

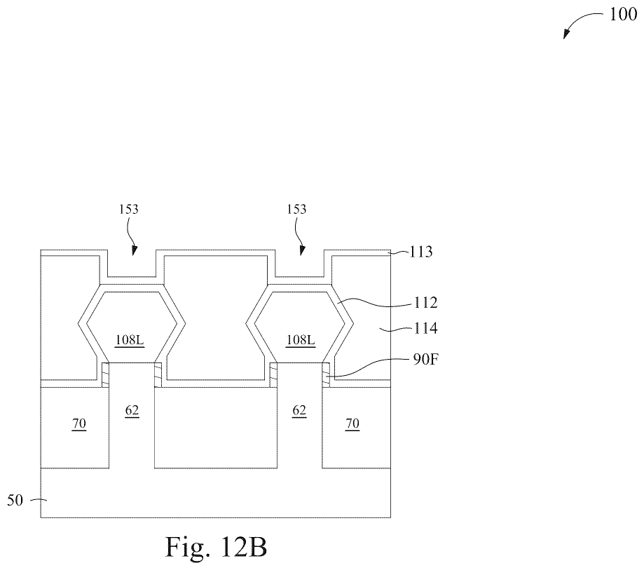

Next, in FIGS. 12A and 12B, a second CESL 113 is formed (e.g., conformally) to line the sidewalls and bottoms of the source/drain recesses 94 and to line the sidewalls and bottoms of the openings 153. The second CESL 113 also extends along the upper surface of the first ILD 114 and along the upper surfaces of the dummy gate structures 85. The material(s) and the formation method of the second CESL 113 may be the same as or similar to those of the first CESL 112, thus details are not repeated here.

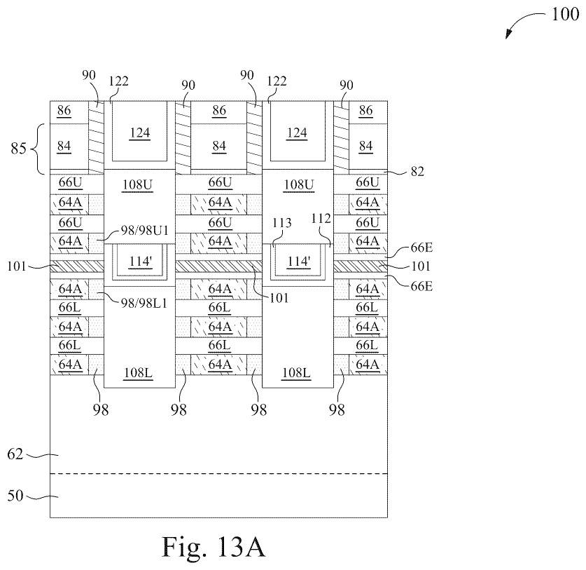

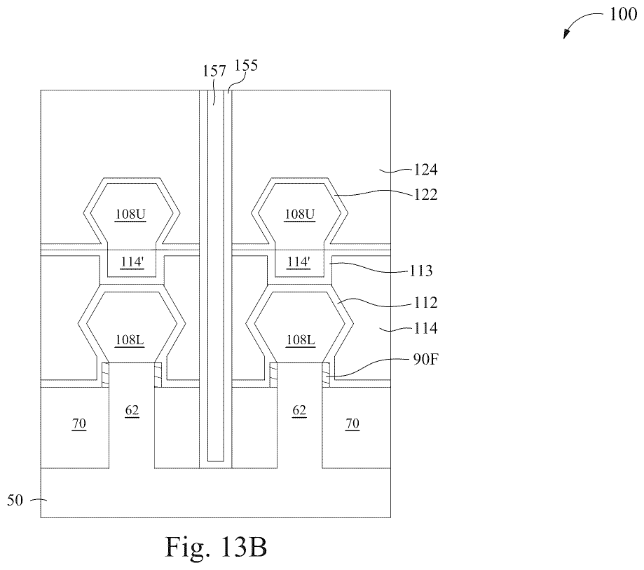

Next, in FIGS. 13A and 13B, a dielectric material 114′ is formed in the openings 153 to fill the openings 153. Excess portions of the dielectric material 114′ (e.g., portions extending above or along the upper surface of the first ILD 114) may be removed by one or more suitable etching processes. After the one or more suitable etching processed are finished, portions of the second CESL 113 along the upper surface of the first ILD 114 are uncovered (e.g., exposed) by the dielectric material 114′. The remaining portions of the dielectric material 114′ inside the openings 153 form dielectric plugs that are embedded in the first ILD 114. The material(s) and the formation method of the dielectric material 114′ may be the same as or similar to those of the first ILD 114, thus details are not repeated here. For ease of discussion, the remaining portions of the dielectric material 114′ inside the openings 153 may also be referred to as dielectric plugs 114′. The first CESL 112, the second CESL 113, the first ILD 114, and the dielectric plugs 114′ may be collectively referred to as dielectric structures 115.

Next, the upper epitaxial source/drain regions 108U (also referred to as upper source/drain regions 108U) are formed in the source/drain recesses 94 over (e.g., directly over) the dielectric plugs 114′. The upper epitaxial source/drain regions 108U may be epitaxially grown from exposed surfaces of the upper semiconductor nanostructures 66U. The materials of the upper epitaxial source/drain regions 108U may be selected from the same candidate group of materials for forming the lower epitaxial source/drain regions 108L, depending on the conductivity type of the upper epitaxial source/drain regions 108U. The conductivity type of the upper epitaxial source/drain regions 108U may be opposite the conductivity type of the lower epitaxial source/drain regions 108L. For example, the upper epitaxial source/drain regions 108U may be oppositely doped from the lower epitaxial source/drain regions 108L. The upper epitaxial source/drain regions 108U may be in-situ doped, and/or may be implanted, with an n-type or p-type dopant. Adjacent upper epitaxial source/drain regions 108U may remain separated after the epitaxy process or may be merged. As discussed above, the lower nanostructure FET and the upper nanostructure FET of the CFET device 100 may be of the same device type (e.g., n-type or p-type), or may be of different device types.

After the upper epitaxial source/drain regions 108U are formed, a third CESL 122 and a second ILD 124 are formed. The materials and the formation methods of the third CESL 122 and the second ILD 124 may be the same as or similar to the materials and the formation methods of the first CESL 112 and the first ILD 114, respectively, thus details are not repeated. The formation process may include depositing the layers for the third CESL 122 and the second ILD 124, and performing a planarization process to remove the excess portions of the corresponding layers. As illustrated in FIG. 13A, after the planarization process, top surfaces of the second ILD 124, the third CESL 122, the gate spacers 90, and the masks 86 are coplanar (within process variations). The planarization process may leave masks 86 unremoved (as shown), or may remove the masks 86, in which case the top surface of the second ILD 124 is level with the top surface of the dummy gate structures 85. The second ILD 124 and the third CESL 122 after the planarization process may be collectively referred to as dielectric structures 123.

In the example of FIG. 13B, a via 157 is formed adjacent to the fins 62, the upper epitaxial source/drain regions 108U, and the lower epitaxial source/drain regions 108L. In the illustrated example, the via 157 is interposed between two adjacent CFETs. The via 157 extends through the second ILD 124, the first ILD 114, the third CESL 122, the second CESL 113, the first CESL 112, and into the isolation regions 70. Notably, a dielectric layer 155 surrounds sidewalls and the bottom surface of the via 157. The bottom surface of the dielectric layer 155 may be level with (e.g., contact) the upper surface of the substrate 50. The number and the location of the via 157 illustrated in FIG. 13B are illustrative and non-limiting.

In some embodiments, to form the dielectric layer 155 and the via 157, one or more anisotropic etching processes are performed to form a via opening that extends through the second ILD 124, the first ILD 114, the third CESL 122, the second CESL 113, the first CESL 112, and into the isolation regions 70. Next, a suitable dielectric material (e.g., silicon nitride) is formed conformally to line sidewalls and the bottom of the via opening. Next, an electrically conductive material, such as copper, tungsten, titanium, titanium nitride, tantalum, tantalum nitride, tantalum carbide, aluminum, ruthenium, cobalt, combinations thereof, multi-layers thereof, or the like, is formed in the via opening and fills the via opening. A planarization process, such as CMP, may be performed next to remove excess portions of the dielectric material and the electrically conductive material from the upper surface of the second ILD 124, and the remaining portions of the dielectric material and the electrically conductive material in the via opening form the dielectric layer 155 and the via 157, respectively.

In some embodiments, the via 157 and the dielectric layer 155 are formed after the replacement gate process discussed hereinafter, using the same or similar formation as discussed above.

Next, in FIGS. 14A-14C, the dummy gate structures 85 are replaced by replacement gate structures in a replacement gate process. The mask 86 (if not removed already) is removed, e.g., by a CMP process. Next, the dummy gate structures 85 are removed in one or more etching steps, so that recesses (also referred to as gate trenches) are formed between the gate spacers 90. In some embodiments, the dummy gates 84 and the dummy dielectrics 82 are removed by an anisotropic dry etch process. For example, the etching process may include a dry etch process using reaction gas(es) that selectively etch the material of the dummy gates 84. Each of the gate trenches exposes and/or overlies portions of nanostructures 66 which act as the channel regions in the resulting devices. The portions of the nanostructures 66 which act as the channel regions are disposed between neighboring pairs of the lower epitaxial source/drain regions 108L or between neighboring pairs of the upper epitaxial source/drain regions 108U. During the removal, the dummy dielectrics 82 may be used as etch stop layers when the dummy gates 84 are etched. The dummy dielectrics 82 may then be removed after the removal of the dummy gates 84.

The remaining portions of the first dummy nanostructures 64A are then removed to form openings (e.g., empty spaces) between the nanostructures 66. The remaining portions of the first dummy nanostructures 64A can be removed by any acceptable etch process that selectively etches the material of the first dummy nanostructures 64A at a faster rate than the materials of the nanostructures 66, the inner spacers 98, and the isolation structures 101. The etching may be isotropic. For example, when the first dummy nanostructures 64A are formed of silicon-germanium, the semiconductor nanostructures 66 are formed of silicon, the inner spacers 98 are formed of silicon oxycarbonitride, and the isolation structures 101 are formed of silicon oxycarbonitride, the etch process may be a wet etch using tetramethylammonium hydroxide (TMAH), ammonium hydroxide (NH₄OH), or the like. In some embodiments, a trimming process (not separately illustrated) is performed to decrease the thicknesses of the exposed portions of the nanostructures 66 and expand the distance between vertically adjacent channel regions (e.g., nanostructures 66).

Next, an interfacial layer 68 is formed at the exterior surfaces of the nanostructures 66. In some embodiments, the interfacial layer 68 is formed of an oxide of a group II-VI material or an oxide of a group IV material. In the illustrated embodiment, the interfacial layer 68 is an oxide of the material of the nanostructures 66, and is formed by an oxidization process (e.g., a thermal oxidization process). In other words, the interfacial layer 68 is formed by converting (e.g., oxidizing) exterior portions of the nanostructures 66 into an oxide (e.g., silicon oxide) of the material (e.g., silicon) of the nanostructures 66. In the illustrated embodiment, the oxidization process also converts exterior portions of the nanostructures 66E and the fins 62 into the interfacial layer 68. Note that in FIG. 14A, the interfacial layer 68 is formed at surfaces of middle portions 66B of the nanostructures 66, and no interfacial layer 68 is formed at surfaces of end portions 66A of the nanostructures 66, which end portions 66A are disposed between vertically adjacent inner spacers 98. This is because the end portions 66A are not exposed to the openings between vertically adjacent nanostructures 66, thus not oxidized by the oxidization process. Similarly, the interfacial layer 68 is formed at surfaces of middle portions 66EB of the nanostructures 66E, and no interfacial layer is formed at surfaces of end portions 66EA of the nanostructures 66E.

In the cross-sectional view of FIG. 14C, the interfacial layer 68 surrounds (e.g., encircles) the nanostructures 66. In some embodiments, no interfacial layer 68 is formed along sidewalls of the isolation structures 101, due to the oxidization process used for forming the interfacial layer 68.

Notably, in FIG. 14C, the interfacial layer 68 surrounds three sidewalls of each nanostructure 66E and forms a U-shape. The fourth sidewall of each nanostructure 66E contacts and extends along the isolation structure 101, thus is not oxidized.

Still referring to FIGS. 14A-14C, next, a gate dielectric layer 132 (also referred to as gate dielectrics) is formed (e.g., conformally) over the interfacial layer 68 and along sidewalls of the isolation structures 101 (see FIG. 14C), such that the gate dielectric layer 132 conformally lines the recesses between gate spacers 90 and lines the openings between the nanostructures 66. Specifically, the gate dielectric layer 132 is formed on the top surfaces of the fins 62; along the top surfaces, the sidewalls, and the bottom surfaces of the nanostructures 66 (on the interfacial layer 68); along the top surfaces, the sidewalls, and the bottom surfaces of the isolation structures 101; and along the sidewalls of the gate spacers 90. The gate dielectric layer 132 wraps around all (e.g., four) sides of the nanostructures 66 and the isolation structures 101. The gate dielectric layer 132 may also be formed on the top surfaces of the third CESL 122, the second ILD 124, and the gate spacers 90, and may be formed along the sidewalls of the fins 62 (e.g., in embodiments where the top surfaces of the isolation regions 70 are below the top surfaces of the fins 62).

The gate dielectric layer 132 may include an oxide such as silicon oxide or a metal oxide, a silicate such as a metal silicate, combinations thereof, multi-layers thereof, or the like. The gate dielectric layer 132 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectric layer 132 may include molecular-beam deposition (MBD), ALD, PECVD, and the like.

Next, lower gate electrodes 134L are formed on the gate dielectrics 132 around the lower nanostructures 66L. For example, the lower gate electrodes 134L wrap around the lower nanostructures 66L. The lower gate electrodes 134L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 134L may include any number of work function tuning layers, any number of barrier layers, any number of glue layers, and a gate fill material (e.g., a metal or metal-containing material).

The lower gate electrodes 134L are formed of material(s) that are suitable for the device type of the lower nanostructure FETs. For example, the lower gate electrodes 134L may include one or more work function tuning layer(s) formed of material(s) that are suitable for the device type of the lower nanostructure FETs. In some embodiments, the lower gate electrodes 134L include an n-type work function tuning layer, which may be formed of titanium aluminum, titanium aluminum carbide, tantalum aluminum, tantalum carbide, combinations thereof, or the like. In some embodiments, the lower gate electrodes 134L include a p-type work function tuning layer, which may be formed of titanium nitride, tantalum nitride, combinations thereof, or the like. Additionally, or alternatively, the lower gate electrodes 134L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 134L may be formed by conformally depositing one or more gate electrode layer(s), then recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 134L may expose the upper semiconductor nanostructures 66U.

In some embodiments, isolation layers 136 are formed on the lower gate electrodes 134L. The isolation layers 136 act as isolation features between the lower gate electrodes 134L and subsequently formed upper gate electrodes 134U. The isolation layers 136 may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 66U. In some embodiments, the isolation layers 136 are omitted. In embodiments where the isolation layers 136 are omitted, the dashed line 135 in FIG. 14C illustrates a conceptional boundary between the lower gate electrode 134L and the upper gate electrode 134U.

Next, upper gate electrodes 134U are formed on the isolation layers 136 (if present) or on the lower gate electrodes 134L. The upper gate electrodes 134U are disposed between the upper nanostructures 66U, and wrap around the upper nanostructures 66U. The upper gate electrodes 134U may be formed of the same candidate materials and candidate processes for forming the lower gate electrodes 134L. The upper gate electrodes 134U are formed of material(s) that are suitable for the device type of the upper nanostructure FETs. For example, the upper gate electrodes 134U may include one or more work function tuning layer(s) formed of material(s) that are suitable for the device type of the upper nanostructure FETs. Although single-layered gate electrodes 134U are illustrated, the upper gate electrodes 134U may include any number of work function tuning layers, any number of barrier layers, any number of glue layers, and a gate fill material.

Additionally, a removal process is performed level top surfaces of the upper gate electrodes 134U and the second ILD 124. In some embodiments, a planarization process such as a CMP, an etch-back process, combinations thereof, or the like may be utilized as the removal process.

After the planarization process, the top surfaces of the upper gate electrodes 134U, the gate dielectrics 132, the second ILD 124, and the gate spacers 90 are substantially coplanar (within process variations). Each respective pair of a gate dielectric 132 and a gate electrode 134 (including an upper gate electrode 134U and a lower gate electrode 134L) may be collectively referred to as a “gate structure” 133 (including upper gate structures 133U and lower gate structures 133L). Each gate structure 133 (may also be referred to as a replacement gate structure, or a metal gate structure) extends along multiple sides (e.g., a top surface, sidewalls, and a bottom surface) of a channel region of a nanostructure 66. The lower gate electrode 134L may also extend along sidewalls and/or a top surface of a fin 62.

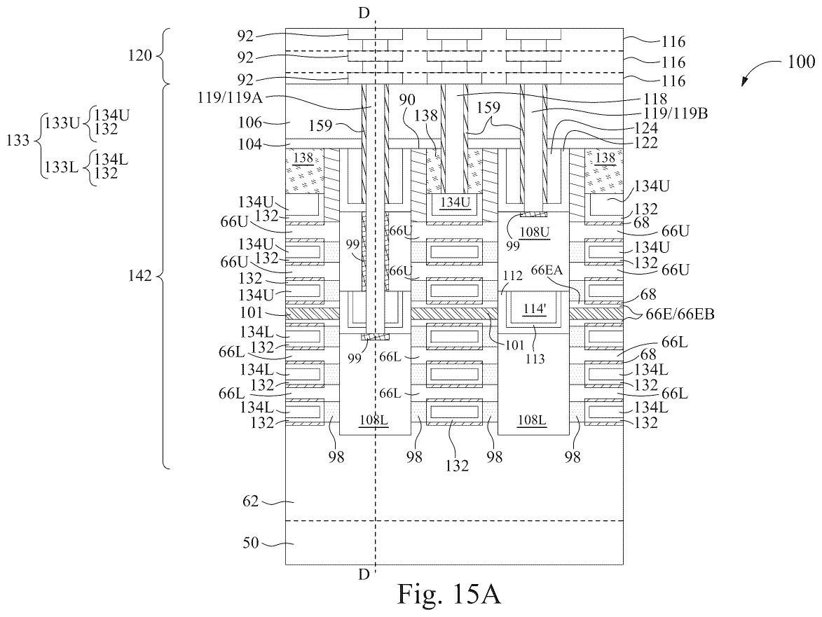

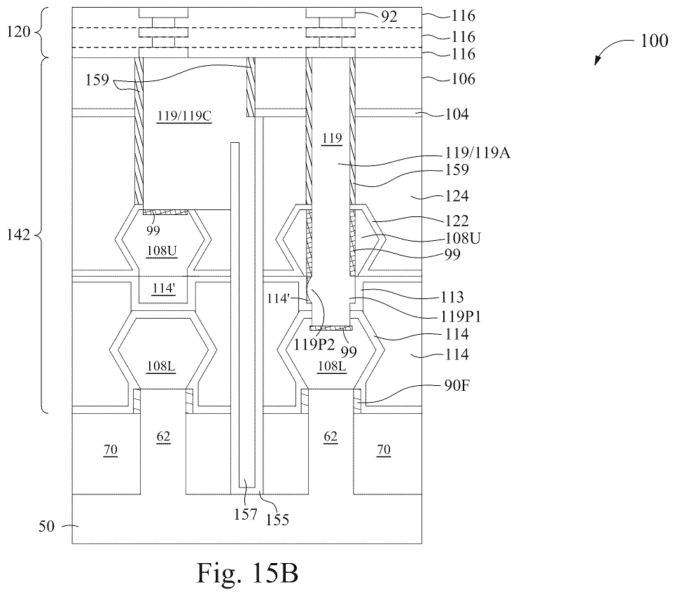

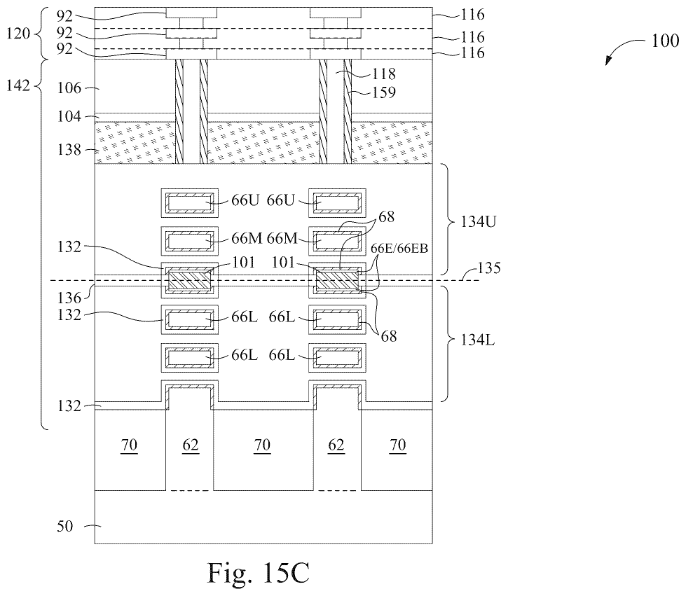

Next, in FIG. 15A-15C, gate masks 138 are formed over the replacement gate structures 133. The formation process may include recessing replacement gate structures 133, filling the resulting recesses with a dielectric material such as silicon nitride, silicon carbonitride, silicon oxynitride, silicon oxycarbonitride, or the like, and performing a planarization process to remove the excess portions of the dielectric material over the second ILD 124.

Next, an ESL 104 and a third ILD 106 are formed over the second ILD 124 and the gate masks 138. In some embodiments, The ESL 104 may include a dielectric material having a high etching selectivity from the etching of the third ILD 106, such as, aluminum oxide, aluminum nitride, silicon nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Next, source/drain contact openings are formed to extend through the various layers overlying the source/drain regions 108 to expose the source/drain regions 108. The source/drain contact openings are subsequently filled with electrically conductive material(s) to form source/drain contact plugs 119. In the example of FIG. 15A, the source/drain contact opening on the right-hand side (corresponding to the source/drain contact plug 119B on the right) extends through the third ILD 106, the ESL 104, the second ILD 124, and the third CESL 122 to expose the upper epitaxial source/drain regions 108U. Notably, the source/drain contact opening on the left-hand side (corresponding to the source/drain contact plug 119A on the left) extends through the third ILD 106, the ESL 104, the second ILD 124, the third CESL 122, the upper epitaxial source/drain region 108U, the dielectric plug 114′, the second CESL 113, and the first CESL 112, and exposes the lower epitaxial source/drain regions 108L. Similarly, gate contact openings are formed to extend through the third ILD 106, the ESL 104, and the gate masks 138 to expose the upper gate electrode 134U.

In some embodiments, a barrier layer 159 is formed in upper portions of the source/drain contact openings before the source/drain contact openings are filled with the electrically conductive material(s). The barrier layer 159 may comprise an electrically conductive material such as titanium nitride, although other materials, such as tantalum nitride, titanium, tantalum, or the like, may alternatively be utilized. The barrier layer 159 may be formed using a CVD process, such as PECVD. However, other alternative processes, such as sputtering or metal organic chemical vapor deposition (MOCVD), ALD, may alternatively be used.

In some embodiments, more than one etching processes (e.g., anisotropic etching processes) are performed sequentially to form the source/drain contact openings, with each subsequent etching process extending (e.g., deepening) the source/drain contact openings formed after the previous etching process(es). The third CESL 122 may be used as a stopping point for one of the etching processes (e.g., a current etching process that etches through the second ILD 124), such that when the third CESL 122 is exposed, the current etching process is stopped. The barrier layer 159 may then be formed (e.g., conformally) to line the sidewalls and the bottoms of the source/drain contact openings. After the barrier layer 159 is formed, the subsequent etching process(es) is performed to extend (e.g., deepen) the source/drain contact openings. The subsequent etching process(es) also removes the horizontal portions of the barrier layer 159 at the bottoms of the source/drain contact openings. To achieve different depths for the different source/drain contact openings, a mask layer (e.g., a patterned photoresist layer) may be formed to shield some of the source/drain contact openings from further etching processes. The mask layer may then be removed after the source/drain contact openings reach their respective target depths. Similar processing may be performed to form barrier layer 159 along sidewalls of the gate contact openings. In some embodiments, the barrier layer 159 is omitted. In the examples of FIGS. 15A-15C, the barrier layer 159 extends from the upper surface of the third ILD 106 to an upper surface of the third CESL 122.

Next, silicide regions 99 are formed on the exposed surfaces of the epitaxial source/drain regions 108. For example, silicide regions 99 are formed on the exposed upper surfaces of the upper epitaxial source/drain regions 108U on the right-hand side of FIG. 15A. In addition, silicide regions 99 are formed on the exposed sidewalls of the upper epitaxial source/drain regions 108U on the left-hand side of FIG. 15A and on the exposed upper surfaces of the lower epitaxial source/drain regions 108L on the left-hand side of FIG. 15A.

In some embodiments, the silicide regions 99 are formed by depositing a metal capable of reacting with semiconductor materials (e.g., silicon, germanium) to form silicide or germanide regions, such as nickel, cobalt, tungsten, titanium, niobium, rhenium, scandium, zirconium, tantalum, platinum, yttrium, hafnium, molybdenum, technetium, other noble metals, other refractory metals, rare earth metals or their alloys, over the exposed surfaces of the epitaxial source/drain regions 108, then performing a thermal anneal process to form the silicide regions 99. The un-reacted portions of the deposited metal are then removed, e.g., by an etching process. Although regions 99 are referred to as silicide regions, regions 99 may also be germanide regions, or silicon germanide regions (e.g., regions comprising silicide and germanide).

Next, source/drain contact plugs 119 are formed in the source/drain contact openings to electrically couple to the epitaxial source/drain regions 108. In addition, gate contact plugs 118 are formed in the gate contact openings to electrically couple to gate electrode (e.g., 134U). The source/drain contact plugs 119 and the gate contact plugs 118 may be formed by filling the source/drain contact openings and the gate contact openings with an electrically conductive material(s), such as tungsten, although other suitable materials such as aluminum, copper, tungsten nitride, rhuthenium, silver, gold, rhodium, molybdenum, nickel, cobalt, cadmium, zinc, alloys of these, combinations thereof, and the like, may alternatively be utilized. A planarization process, such as CMP, may be performed to remove excess portions of the electrically conducive material(s) that are disposed outside of the source/drain contact openings and the gate contact openings. The source/drain contact plugs 119 (may also be referred to as source/drain contacts) and the gate contact plugs 118 (may also be referred to as gate contacts) are in contact with respective silicide regions 99.

In the examples of FIGS. 15A-15C, the source/drain contact plugs 119A extends vertically through the upper epitaxial source/drain region 108U to the lower epitaxial source/drain region 108L, thus directly connecting the upper epitaxial source/drain region 108U to the lower epitaxial source/drain region 108L. FIG. 15B illustrates the cross-section of FIG. 15A along cross-section D-D in FIG. 15A, which cross-section D-D corresponds to cross-section B-B in FIG. 1.

In FIG. 15B, the portion of the source/drain contact plug 119A embedded in the dielectric plug 114′ is wider than other portions above (e.g., a portion between the silicide regions 99 along sidewalls of the upper epitaxial source/drain region 108U) or below (e.g., a portion in the lower epitaxial source/drain region 108L). For example, the source/drain contact plug 119A may have protrusion portions 119P (e.g., a left-side protrusion portion 119P2 and a right-side protrusion portion 119P1) that extend outwards laterally. The protrusion portions 119P may contact the second CESL 113. The protrusion portions 119P may be caused by a pre-cleaning process (e.g., an isotropic etching process) performed after the source/drain contact openings are formed and before the electrically conductive material(s) fills the source/drain contact openings. The pre-cleaning process is performed to remove by-products and/or residues from previous etching processes. The pre-cleaning process may unintentionally remove (e.g., etch away) the material of the dielectric plug 114′, thus increasing the width of the source/drain contact opening at the location of the dielectric plug 114′. For example, the pre-cleaning process may result in curved sidewalls of the source/drain contact opening. The widened sidewalls of the source/drain contact opening due to the pre-cleaning process increase the width of the source/drain contact opening, and this phenomenon is referred to as the “bowing of the source/drain contact openings,” or “bowing issue” for short. Note that the second CESL 113 limits the extent of the bowing issue. The maximum amount of increase in the width of the source/drain contact opening at the location of the dielectric plug 114′ is limited by the second CESL 113 surrounding the dielectric plug 114′.

Depending on various factors, such as the materials of the dielectric plug 114′, the etchant used in the pre-cleaning process, the etching conditions, the size of the source/drain contact opening, whether the center axis of the source/drain contact opening is aligned with the center axis of the dielectric plug 114′, and so on, the pre-cleaning process may result in various sidewall profiles for the source/drain contact opening at the location of the dielectric plug 114′, which in turn results in corresponding different sidewall profiles for the source/drain contact plug 119A. In the example of FIG. 15B, at the location of the dielectric plug 114′, the left-side protrusion 119P2 of the source/drain contact plug 119A has a curved sidewall, and there are residue portions of the dielectric plug 114′ disposed between the left-side protrusion 119P2 and the second CESL 113. The right-side protrusion 119P1 of the source/drain contact plug 119A has a straight sidewall, and there is no residue portion of the dielectric plug 114′ left between the right-side protrusion 119P1 and the second CESL 113. In other embodiments, the left-side protrusion 119P2 and the right-side protrusion 119P1 have substantially symmetric sidewall profiles. These and other variations are fully intended to be included within the scope of the present disclosure.

The bowing of the source/drain contact opening may cause problems for conventional designs without the structure and methods disclosed herein. For example, for conventional designs without the second CESL 113 around the dielectric plugs 114′, there is no constraint on the increase in the width of the source/drain contact opening due to the bowing issue, and the source/drain contact opening may have a very large widened portion between the upper epitaxial source/drain region 108U and the lower epitaxial source/drain region 108L. When the source/drain contact opening is filled with the electrically conductive material to form the source/drain contact plug 119A, the widened portion of the source/drain contact opening may not be filled completely, and void (e.g., empty space) may form in the widened portion. The void may increase the electrically resistance of the source/drain contact plug 119A, thus adversely affect the device performance. In addition, if the bowing issue causes the widened portion of the source/drain contact opening to expose the adjacent via 157, electrical short may happen when the source/drain contact opening is filled with electrically conductive material(s). Furthermore, even without the electrical short problem, the widened portion of the source/drain contact plug 119A caused by the bow issue may result in increased leakage current, due to the reduced laterally distance between the via 157 and the widened portion of the source/drain contact plug 119A. The structure and methods disclosed herein, by forming the second CESL 113 around the dielectric plugs 114′, and by forming the source/drain contact opening of the source/drain contact plug 119A to extend through the dielectric plugs 114′, avoids the above problems caused by the bowing issue, thus reducing the electrical resistance of the source/drain contact plug 119A, reducing the leakage current, and avoids electrical short between the source/drain contact plug 119A and adjacent conductive features (e.g., the via 157).

FIG. 15B further illustrates a source/drain contact plug 119C that electrically couples the upper epitaxial source/drain region 108U on the left side to the via 157. The source/drain contact plug 119C is formed to be wider than the source/drain contact plug 119A, such that a portion of the source/drain contact plug 119C overlies and is electrically coupled to, the upper epitaxial source/drain region 108U, and another portion of the source/drain contact plug 119C overlies and is electrically coupled to the via 157. The barrier layer 159 is formed along sidewalls of the source/drain contact plug 119C, and the silicide region 99 is formed on the upper surface of the upper epitaxial source/drain region 108U. Note that in FIG. 15B, the barrier layer 159 along the right sidewall of the source/drain contact plug 119C is disposed laterally between opposing sidewalls of the dielectric layer 155 facing the via 157, which allows the source/drain contact plug 119C to be in direct contact with the via 157. The layers of the semiconductor device 100 disposed between upper portions of the fins 62 and the third ILD 106 are collectively referred to as the device layer 142 of the semiconductor device 100.

Still referring to FIGS. 15A-15C, next, a front-side interconnect structure 120 is formed on the device layer 142. The front-side interconnect structure 120 includes dielectric layers 116 and layers of conductive features 92 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers.

The conductive features 92 may include conductive lines and vias, which may be formed using, e.g., damascene processes. Conductive features 92 may include metal lines and vias, which may include diffusion barriers and a copper containing material over the diffusion barriers. There may also be aluminum pads over and electrically connected to the metal lines and vias. Depending on how the respective die is to be packaged, the top surface features among the conductive features 92 may include bond pads, metal pillars, solder regions, and/or the like.

Additional processing may be performed to finish the fabrication of the semiconductor device 100. For example, a backside interconnect structure may be formed at the backside of the semiconductor device 100, and a dicing process may be performed to separate semiconductor devices 100 formed on a same wafer into separate (e.g., individual) semiconductor devices 100. In some embodiments, the front-side interconnect structure 120 is attached to a carrier, (e.g., a glass carrier, a silicon carrier, or the like), and a backside thinning process is performed to remove the substrate 50 and at least lower portions of the fins 62. The backside thinning process may also remove a portion of the dielectric layer 155 (e.g., the portion along the bottom surface of the via 157) to expose the via 157 at the backside of the semiconductor device 100. Next, a fourth ILD is formed at the backside of the semiconductor device 100, and additional source/drain contact plugs and/or additional gate contact plugs may be formed in the fourth ILD to electrically couple to, e.g., the lower epitaxial source/drain regions 108L, the lower gate structures 133L, and the vias 157. Next, a backside interconnect structure, which is same as or similar to the front-side interconnect structure 120, is formed on the fourth ILD 107 and is electrically coupled to the additional source/drain contact plugs and/or the additional gate contact plugs. The materials and the formation methods of the above features are the same as or similar to those discussed above, thus details are not repeated here.

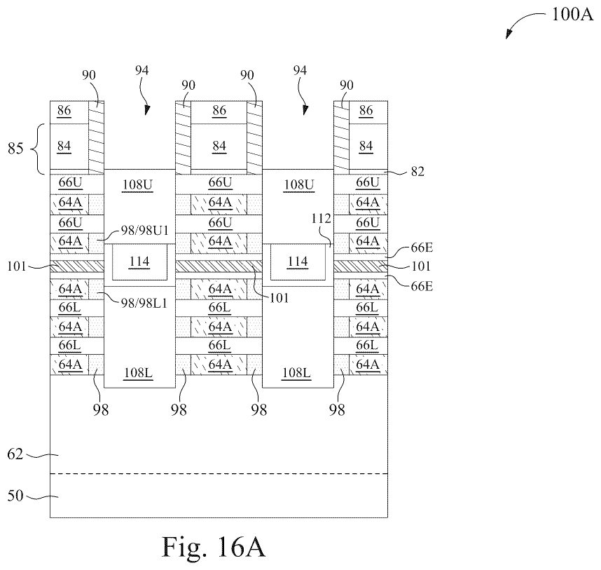

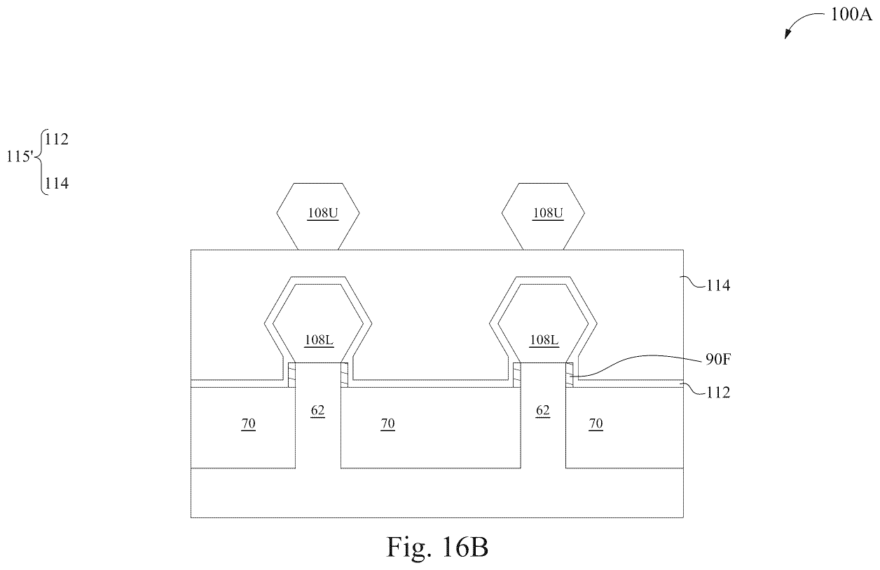

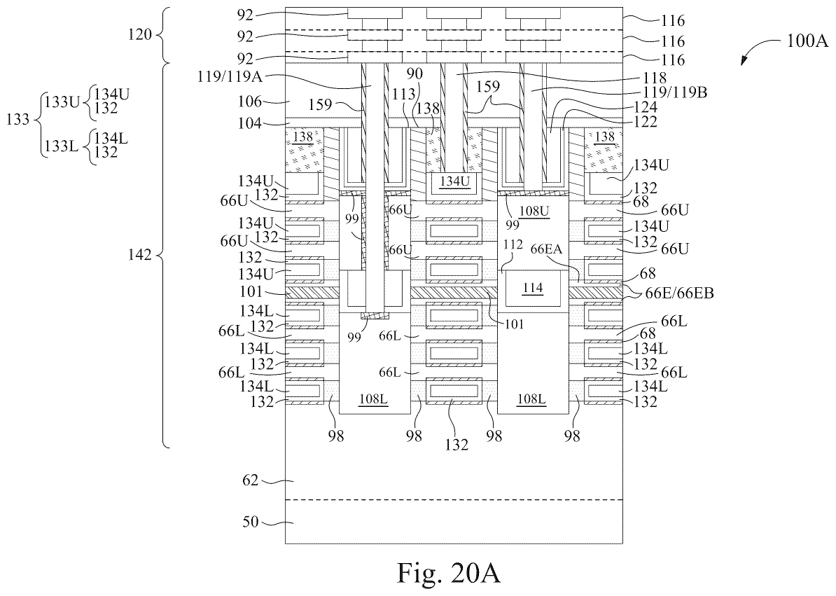

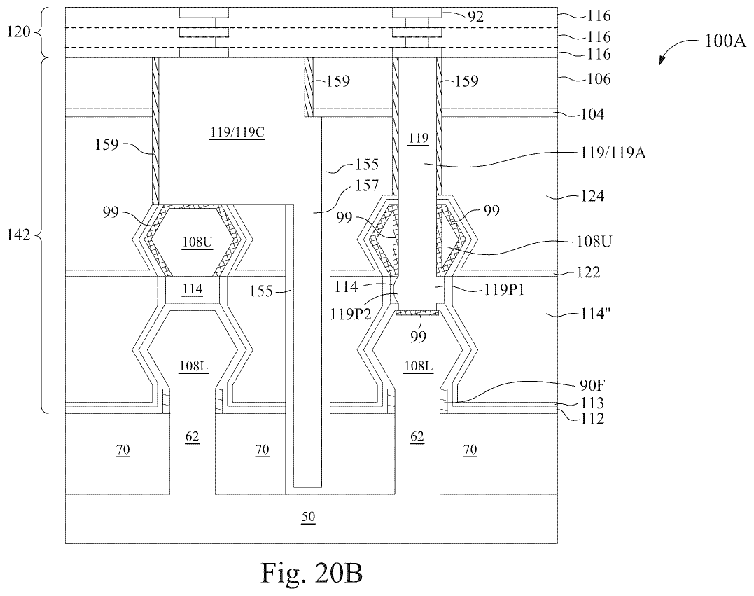

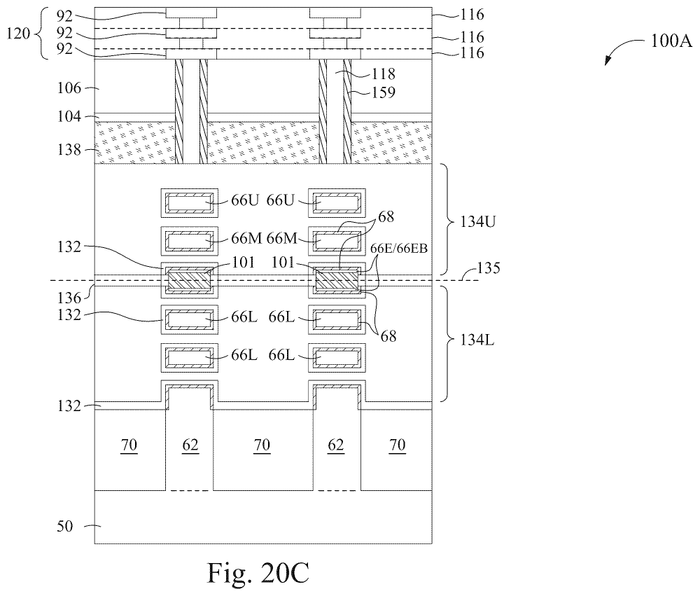

FIGS. 16A, 16B, 17A, 17B, 18A, 18B, 19A, 19B, 20A, 20B, and 20C are cross-sectional views of a semiconductor device 100A at various stages of manufacturing, in accordance with another embodiment. FIGS. 16A, 17A, 18A, 19A, and 20A are cross-sectional views along cross-section A-A in FIG. 1. FIGS. 16B, 17B, 18B, 19B, and 20B are cross-sectional views along cross-section B-B in FIG. 1. FIG. 20C are cross-sectional views along cross-section C-C in FIG. 1.

The processing of FIGS. 16A and 16B follows the processing of FIGS. 10A and 10B. In other words, FIGS. 2, 3A, 3B, 4, 5, 6, 7, 8, 9A, 9B, 10A, 10B, 16A, 16B, 17A, 17B, 18A, 18B, 19A, 19B, 20A, 20B, and 20C illustrate the processing steps of the semiconductor device 100A.

In FIGS. 16A and 16B, the upper epitaxial source/drain regions 108U are formed in the source/drain recesses 94 on the first ILD 114, using the same or similar formation method as discussed above for the upper epitaxial source/drain regions 108U, thus details are not repeated here.

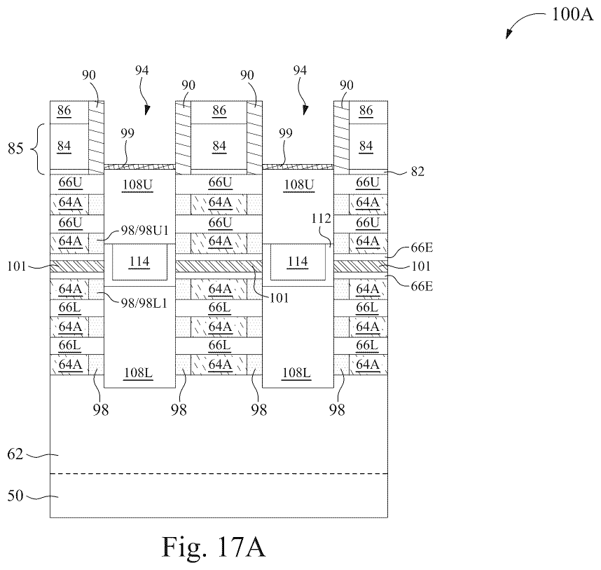

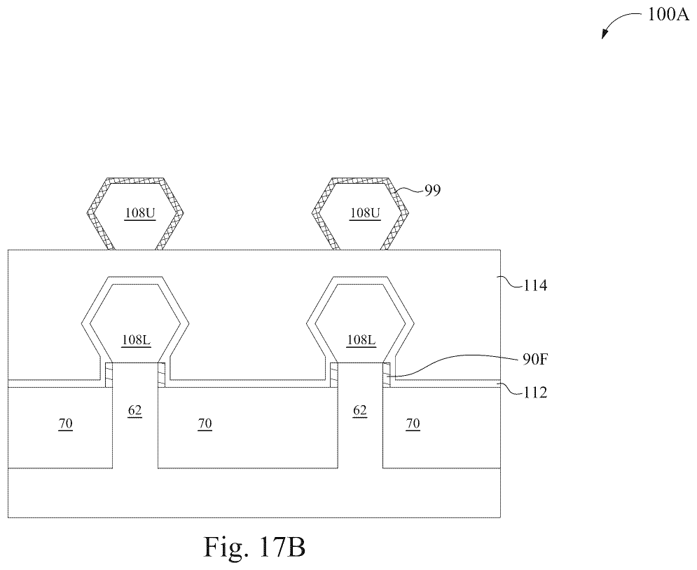

Next, in FIGS. 17A and 17B, silicide regions 99 are formed along exterior surfaces (e.g., surfaces exposed to the source/drain recesses 94) of the upper epitaxial source/drain regions 108U. Note that in the example of FIGS. 17A and 17B, the silicide regions 99 extends along the top surfaces and sidewalls of the upper epitaxial source/drain regions 108U.

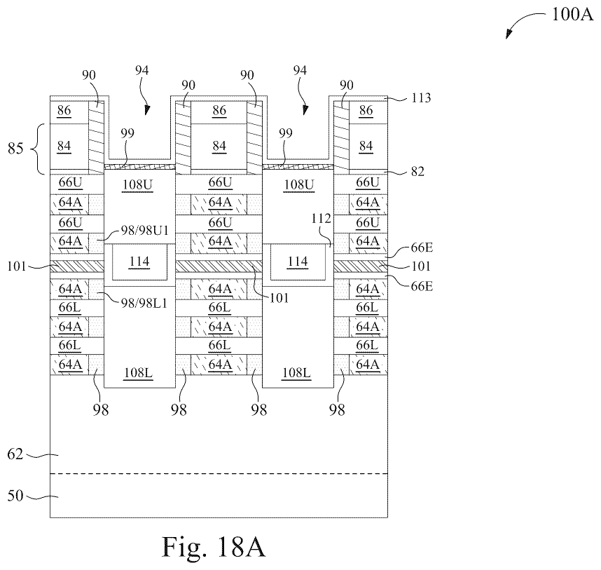

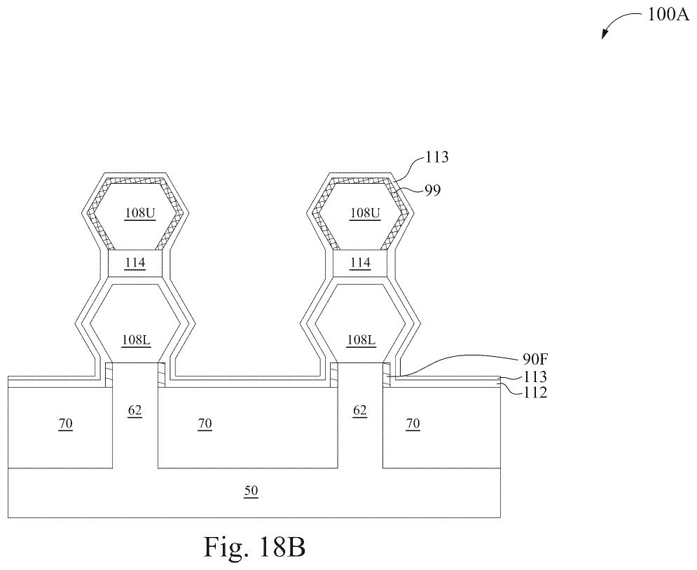

Next, in FIGS. 18A and 18B, an anisotropic etching process is performed using the silicide regions 99 as an etching mask. The anisotropic etching process may be performed using an etchant selective to the material of the first ILD 114 (e.g., silicon oxide). For example, an anisotropic etching process using an etching gas that comprises CF₄, Cl2, SO₂, or a mixture of NHF₃ and HF may be performed. After the anisotropic etching process, remaining portions of the first ILD 114 are disposed between the upper epitaxial source/drain regions 108U and the lower epitaxial source/drain regions 108L, and the first CESL 112 is exposed. Next, as illustrated in FIG. 18B, the second CESL 113 is formed conformally along the silicide regions 99, along the sidewalls of the remaining portions of the first ILD 114, and along the first CESL 112. In addition, the second CESL 113 is also formed conformally along the sidewalls of the gate spacers 90 and along the upper surface of the dummy gate structures 85, as illustrated in FIG. 15A.

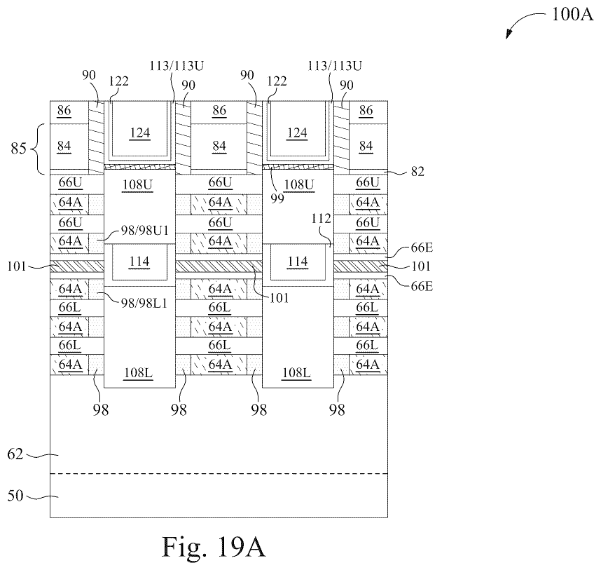

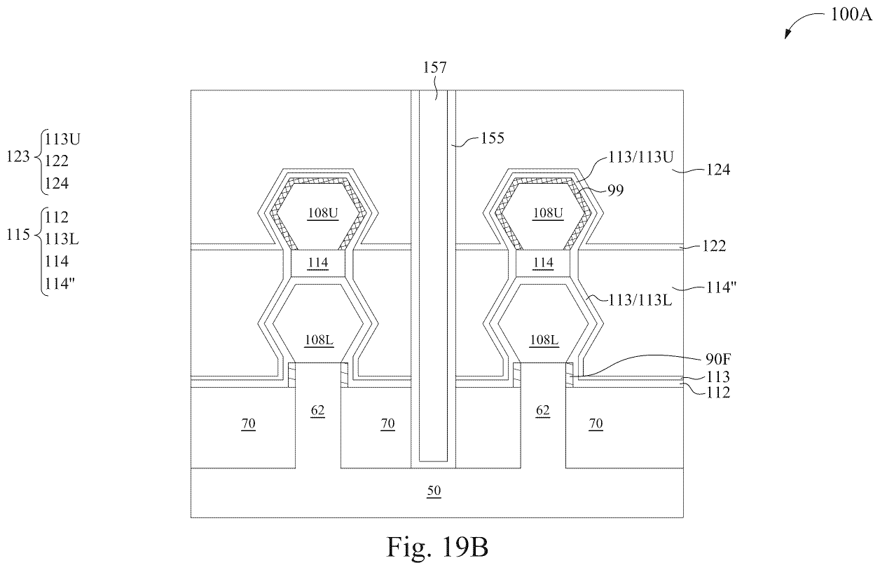

Next, in FIGS. 19A and 19B, a dielectric material 114″ (see FIG. 19B) is formed over the second CESL 113. The dielectric material 114″ may be the same material as the first ILD 114 and may be formed using the same or similar formation method, thus details are not repeated. In some embodiments, after being formed, the dielectric material 114″ extends further from the substrate 50 than the silicide regions 99. Next, the dielectric material 114″ is etched back by a suitable etching process, such that the upper surface of the dielectric material 114″ is level with the upper surface of the remaining portions of the first ILD 114. For ease of discussion, portions of the second CESL 113 disposed below the upper surface of the remaining portions of the first ILD 114 are referred to as CESL 113L, and portions of the second CESL 113 disposed above the upper surface of the remaining portions of the first ILD 114 are referred to as CESL 113U. The dielectric material 114″, the remaining portions of the first ILD 114, the first CESL 112, and the CESL 113L are collectively referred to as dielectric structures 115. The remaining portions of the first ILD 114 may also be referred to as dielectric plugs 114.

Next, the third CESL 122 is formed (e.g., conformally) over the upper surface of the dielectric material 114″ and the silicide regions 99. Next, the second ILD 124 is formed over the third CESL 122. A planarization process, such as CMP, may be performed next to achieve a coplanar upper surface between the masks 86, the gate spacers 90, the third CESL 122, the CESL 113U, and the second ILD 124. After the planarization process, the third CESL 122, the CESL 113U, and the second ILD 124 are collectively referred to as dielectric structures 123.

FIG. 19B further illustrates a via 157 and a dielectric layer 155 around the sidewalls and the bottom surface of the via 157. The via 157 and the dielectric layer 155 may be formed using the same material(s) and formation methods as discussed above, thus details are not repeated.

Next, in FIGS. 20A-20C, the dummy gate structures 85 are removed and replaced by replacement gate structures 133, following the same or similar processing discussed above, thus details are not repeated. The replacement gate structures 133 includes gate dielectric layers 132 and gate electrodes 134 (e.g., upper gate electrodes 134U and lower gate electrodes 134L). Interfacial layers 68 may be formed before the gate dielectric layers 132 are formed.

Next, the upper gate structures 133U are recessed, and the gate masks 138 are formed on the recessed upper gate structures 133U. Next, the ESL 104 and the third ILD 106 are formed over the second ILD 124, and the source/drain contact plugs 119 (e.g., 119A, 119B, 119C) and gate contact plugs 118 are formed to be electrically coupled to the source/drain regions 108 and the upper gate structures 133U, respectively.

FIG. 20B illustrates the source/drain contact plug 119A that extends through the third ILD 106, the ESL 104, the third CESL 122, the second CESL 113, the upper epitaxial source/drain region 108U, the dielectric plug 114, the first CESL 112, and into the lower epitaxial source/drain region 108L. Silicide regions 99 are formed along sidewalls of the upper epitaxial source/drain region 108U, and the on the upper surface of the lower epitaxial source/drain region 108L. Notably, in FIG. 20B, a first portion of the silicide regions 99 extends along the sidewalls of the upper epitaxial source/drain region 108U facing the source/drain contact plug 119A, and a second portion of the silicide regions 99 (e.g., the silicide regions 99 formed in FIGS. 17A and 17B) extends along the exterior surfaces of the upper epitaxial source/drain region 108U. The first portion and the second portion of the silicide regions 99 may completely encapsulate (e.g., surround) a portion of the upper epitaxial source/drain region 108U, as illustrated by the silicide regions 99 at the right side of the source/drain contact plug 119A. In FIG. 20B, the portions of the silicide regions 99 at the left side of the source/drain contact plug 119A leaves a gap at the bottom of the upper epitaxial source/drain region 108U, thus does not completely encapsulate the portion of the upper epitaxial source/drain region 108U at the left side of the source/drain contact plug 119A. In some embodiments, the silicide regions 99 completely encapsulate both portions (e.g., at the left side and the right side of the source/drain contact plug 119A) of the upper epitaxial source/drain region 108U. In some embodiments, the silicide regions 99 does not completely encapsulate either portions (e.g., at the left side or the right side of the source/drain contact plug 119A) of the upper epitaxial source/drain region 108U.

Note that in FIG. 20B, the source/drain contact plug 119A is formed to extend through the dielectric plug 114 between opposing sidewalls of the second CESL 113. As illustrated in FIG. 20B, the portion of the source/drain contact plug 119A at the location of the dielectric plug 114 may experience the bowing issue due to the pre-cleaning process. However, for similar reason as discussed above, the second CESL 113 limits the bowing to within the area defined by the opposing sidewalls of the second CESL, thus preventing void (e.g., empty space) from being formed in the source/drain contact plug 119A and reducing the electrical resistance of the source/drain contact plug 119A. In addition, electrical short between the source/drain contact plug 119A and an adjacent conductive feature (e.g., the via 157) is prevented, and the leakage current between the source/drain contact plug 119A and an adjacent conductive feature (e.g., the via 157) is eliminated or reduced.

FIG. 20B shows similar protrusion portions 119P1 and 119P2 in the widened portion of the source/drain contact plug 119A as non-limiting examples. Other shapes for the protrusion portions 119P1 and 119P2 are also possible, as skilled artisans readily appreciate. FIG. 20B also illustrates the barrier layer 159 formed around upper portions of the source/drain contact plug 119A, and around the source/drain contact plug 119C. Details are the same as or similar to those discussed above, thus not repeated. Next, the front-side interconnect structure 120 is formed over the third ILD 106, using the same or similar processing steps discussed above.

Additional processing may be performed to finish the fabrication of the semiconductor device 100A. For example, a backside thinning process may be performed to expose the via 157 at the backside of the semiconductor device 100A. The backside interconnect structure may be formed at the backside of the semiconductor device 100A. A dicing process may be performed to separate semiconductor devices 100A formed on a same wafer into separate semiconductor devices 100A. The details are the same as or similar to those discussed above, thus not repeated.

Advantages are achieved by the disclosed embodiments. Complementary FET (CFET) structures, by stacking devices in bottom and top layers of the semiconductor device, offer promising potential for advanced logic technology due to the ability to achieve high transistor integration density. The disclosed embodiments, by forming the second CESL 113 around the dielectric plug (e.g., 114′ in FIG. 13B, or 114 in FIG. 18B), and by forming the source/drain contact plug 119A to extend through the dielectric plug and between opposing sidewalls of the CESL 113, prevents void (e.g., empty space) from being formed in the source/drain contact plug 119A and reduces the electrical resistance of the source/drain contact plug 119A. In addition, electrical short and/or leakage current between the source/drain contact plug 119A and an adjacent conductive feature (e.g., the via 157) are prevented, thus increasing device reliability and production yield and reducing power consumption. The disclosed embodiments also allow conductive features (e.g., the via 157) to be formed closer to the source/drain contact plug 119A, thus providing more flexibility in the design of the CFET devices and higher integration density, which also reduces the production cost.

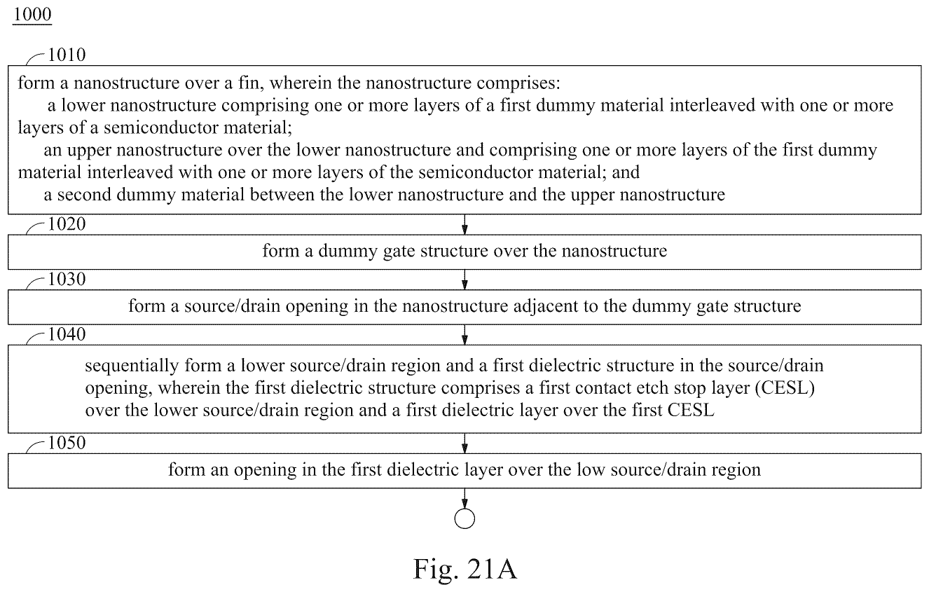

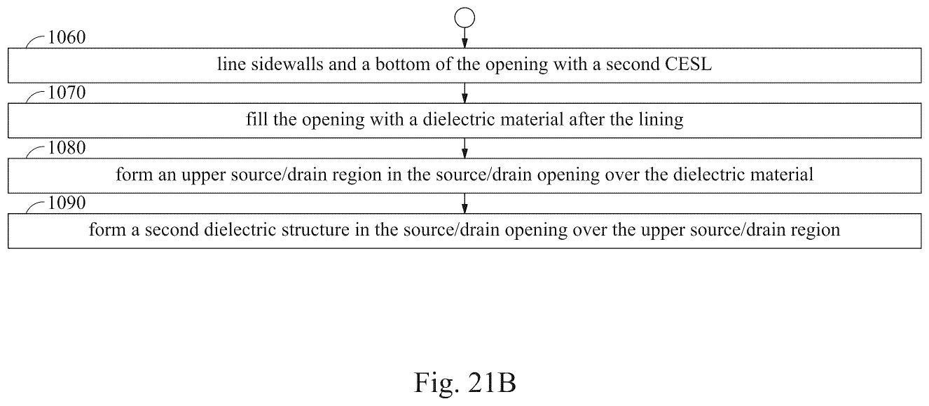

FIGS. 21A and 21B together illustrate a flow chart of a method 1000 of forming a semiconductor device, in accordance with some embodiments. It should be understood that the embodiment method shown in FIGS. 21A and 21B is merely an example of many possible embodiment methods. One of ordinary skill in the art would recognize many variations, alternatives, and modifications. For example, various steps as illustrated in FIGS. 21A and 21B may be added, removed, replaced, rearranged, or repeated.

Referring to FIGS. 21A and 21B, at block 1010, a nanostructure is formed over a fin, wherein the nanostructure comprises: a lower nanostructure comprising one or more layers of a first dummy material interleaved with one or more layers of a semiconductor material; an upper nanostructure over the lower nanostructure and comprising one or more layers of the first dummy material interleaved with one or more layers of the semiconductor material; and a second dummy material between the lower nanostructure and the upper nanostructure. At block 1020, a dummy gate structure is formed over the nanostructure. At block 1030, a source/drain opening is formed in the nanostructure adjacent to the dummy gate structure. At block 1040, a lower source/drain region and a first dielectric structure are sequentially formed in the source/drain opening, wherein the first dielectric structure comprises a first contact etch stop layer (CESL) over the lower source/drain region and a first dielectric layer over the first CESL. At block 1050, an opening is formed in the first dielectric layer over the lower source/drain region. At block 1060, sidewalls and a bottom of the opening are lined with a second CESL. At block 1070, the opening is filled with a dielectric material after the lining. At block 1080, an upper source/drain region is formed in the source/drain opening over the dielectric material. At block 1090, a second dielectric structure is formed in the source/drain opening over the upper source/drain region.

In an embodiment, a method of forming a semiconductor device includes: forming a nanostructure over a fin, wherein the nanostructure comprises: a lower nanostructure comprising one or more layers of a first dummy material interleaved with one or more layers of a semiconductor material; an upper nanostructure over the lower nanostructure and comprising one or more layers of the first dummy material interleaved with one or more layers of the semiconductor material; and a second dummy material between the lower nanostructure and the upper nanostructure. The method further includes: forming a dummy gate structure over the nanostructure; forming a source/drain opening in the nanostructure adjacent to the dummy gate structure; sequentially forming a lower source/drain region and a first dielectric structure in the source/drain opening, wherein the first dielectric structure comprises a first contact etch stop layer (CESL) over the lower source/drain region and a first dielectric layer over the first CESL; forming an opening in the first dielectric layer over the lower source/drain region; lining sidewalls and a bottom of the opening with a second CESL; filling the opening with a dielectric material after the lining; forming an upper source/drain region in the source/drain opening over the dielectric material; and forming a second dielectric structure in the source/drain opening over the upper source/drain region. In an embodiment, the second dielectric structure comprises a third CESL over the upper source/drain region and a second dielectric layer over the third CESL. In an embodiment, the method further comprises, after forming the second dielectric structure, forming a via that electrically couples the upper source/drain region and the lower source/drain region, wherein forming the via comprises: forming a via opening that extends through the second dielectric structure, through the upper source/drain region, through the dielectric material, through the second CESL, through the first CESL, and into the lower source/drain region; and filling the via opening with an electrically conductive material. In an embodiment, the via opening is disposed laterally between opposing sidewalls of the second CESL facing the dielectric material. In an embodiment, the via opening exposes sidewalls of the second dielectric layer, wherein forming the via further comprises, before filling the via opening, lining the sidewalls of the second dielectric layer with a barrier layer. In an embodiment, the via opening exposes sidewalls of the upper source/drain region and an upper surface of the lower source/drain region, wherein forming the via further comprises, before filling the via opening, forming silicide regions along the sidewalls of the upper source/drain region and along the upper surface of the lower source/drain region. In an embodiment, the dummy gate structure overlies a first portion of the nanostructure, wherein the method further comprises, after forming the source/drain opening and before sequentially forming the lower source/drain region and the first dielectric structure: replacing the second dummy material in the first portion of the nanostructure with an isolation structure; and replacing end portions of the first dummy material exposed by the source/drain opening with inner spacers. In an embodiment, replacing the end portions of the first dummy material comprises: removing the end portions of the first dummy material exposed by the source/drain opening to form sidewall recesses in the first dummy material; lining sidewalls and a bottom of the source/drain opening with an inner spacer layer, wherein the inner spacer layer fills the sidewall recesses; and performing an anisotropic etching process to remove portions of the inner spacer layer disposed outside the sidewall recesses. In an embodiment, the method further comprises, after forming the second dielectric structure, replacing the dummy gate structure with a replacement gate structure. In an embodiment, replacing the dummy gate structure comprises: removing the dummy gate structure to form a gate trench, wherein the gate trench exposes the first portion of the nanostructure; selectively removing the first dummy material in the first portion of the nanostructure, wherein after the selective removing, the semiconductor material in the upper nanostructure and the lower nanostructure of the first portion of the nanostructure forms upper channel regions and lower channel regions, respectively, of the semiconductor device; forming a gate dielectric material around the upper channel regions and the lower channel regions; and forming a gate electrode material around the gate dielectric material. In an embodiment, replacing the dummy gate structure further comprises: after forming the gate electrode material, recessing the gate electrode material below an upper surface of the isolation structure distal from the fin, wherein the recessed gate electrode material around the lower channel regions forms a lower gate electrode; forming an isolation layer over the lower gate electrode; and after forming the isolation layer, forming an upper gate electrode by forming the gate electrode material around the upper channel regions.

In an embodiment, a method of forming a semiconductor device includes: forming a nanostructure over a fin, wherein the nanostructure comprises: a lower nanostructure comprising one or more layers of a first dummy material interleaved with one or more layers of a semiconductor material; an upper nanostructure over the lower nanostructure and comprising one or more layers of the first dummy material interleaved with one or more layers of the semiconductor material; and a second dummy material between the lower nanostructure and the upper nanostructure. The method further includes: forming a dummy gate structure over the nanostructure; forming a source/drain opening in the nanostructure adjacent to the dummy gate structure; sequentially forming a lower source/drain region and a first dielectric structure in the source/drain opening, wherein the first dielectric structure comprises a first contact etch stop layer (CESL) that extends conformally along exterior surfaces of the lower source/drain region and comprises a first dielectric layer over the first CESL; forming an upper source/drain region in the source/drain opening over the first dielectric structure; forming silicide regions along exterior surfaces of the upper source/drain region; performing an anisotropic etching process using the silicide regions as an etching mask, wherein the anisotropic etching process uses an etchant that selectively removes the first dielectric layer, wherein a first portion of the first dielectric layer under the upper source/drain region remains after the anisotropic etching processing; after performing the anisotropic etching process, forming a second CESL that extends conformally along the silicide regions, along sidewalls of the first portion of the first dielectric layer, and along the first CESL; and after forming the second CESL, forming a second dielectric layer in the source/drain opening around the lower source/drain region and around the first portion of the first dielectric layer. In an embodiment, the upper source/drain region extends above the second dielectric layer, wherein the method further comprises forming a third dielectric layer over the second dielectric layer and around the upper source/drain region. In an embodiment, the method further comprises, after forming the second dielectric layer and before forming the third dielectric layer, forming a third CESL over the second CESL and around the upper source/drain region. In an embodiment, the method further comprises, after forming the second dielectric layer, forming a via that electrically couples the upper source/drain region and the lower source/drain region, wherein forming the via comprises: forming a via opening that extends through the silicide regions, through the upper source/drain region, through the first portion of the first dielectric layer, through the first CESL, and into the lower source/drain region; and filling the via opening with an electrically conductive material. In an embodiment, the via opening is disposed laterally between opposing sidewalls of the second CESL facing the first portion of the first dielectric layer.

In an embodiment, a semiconductor device includes: a substrate; lower channel regions disposed vertically over the substrate; upper channel regions disposed vertically over the lower channel regions; an isolation structure between the lower channel regions and the upper channel regions; a lower source/drain region at first ends of the lower channel regions; an upper source/drain region at second ends of the upper channel regions; and a dielectric structure between the lower source/drain region and the upper source/drain region, wherein the dielectric structure comprises: a first contact etch stop layer (CESL) extending conformally along exterior surfaces of the lower source/drain region; a dielectric plug between the lower source/drain region and the upper source/drain region; a second CESL lining sidewalls of the dielectric plug and contacting the first CESL; and a dielectric layer contacting and extending along the first CESL and the second CESL, wherein the lower source/drain region and the dielectric plug are embedded in the dielectric layer. The semiconductor device further includes: a lower gate electrode around the lower channel regions; and an upper gate electrode around the upper channel regions. In an embodiment, the semiconductor device further comprises a fin base protruding over the substrate, wherein the lower channel regions and the upper channel regions are disposed vertically over the fin base, wherein the second CESL further extends along a bottom surface of the dielectric plug facing the lower source/drain region. In an embodiment, the semiconductor device further comprises a via that extends through the upper source/drain region, through the dielectric plug, through the second CESL, through the first CESL, and into the lower source/drain region, wherein the via is disposed laterally between opposing sidewalls of the second CESL. In an embodiment, the semiconductor device further comprises: a first silicide region between the via and the upper source/drain region; and a second silicide region along an upper surface of the lower source/drain region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein.

Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming a nanostructure over a fin, wherein the nanostructure comprises:
a lower nanostructure comprising one or more layers of a first dummy material interleaved with one or more layers of a semiconductor material;
an upper nanostructure over the lower nanostructure and comprising one or more layers of the first dummy material interleaved with one or more layers of the semiconductor material; and
a second dummy material between the lower nanostructure and the upper nanostructure;
forming a dummy gate structure over the nanostructure;
forming a source/drain opening in the nanostructure adjacent to the dummy gate structure;
sequentially forming a lower source/drain region and a first dielectric structure in the source/drain opening, wherein the first dielectric structure comprises a first contact etch stop layer (CESL) over the lower source/drain region and a first dielectric layer over the first CESL;
forming an opening in the first dielectric layer over the lower source/drain region;
lining sidewalls and a bottom of the opening with a second CESL;
filling the opening with a dielectric material after the lining;
forming an upper source/drain region in the source/drain opening over the dielectric material; and
forming a second dielectric structure in the source/drain opening over the upper source/drain region.

2. The method of claim 1, wherein the second dielectric structure comprises a third CESL over the upper source/drain region and a second dielectric layer over the third CESL.

3. The method of claim 2, further comprising, after forming the second dielectric structure, forming a via that electrically couples the upper source/drain region and the lower source/drain region, wherein forming the via comprises:
forming a via opening that extends through the second dielectric structure, through the upper source/drain region, through the dielectric material, through the second CESL, through the first CESL, and into the lower source/drain region; and
filling the via opening with an electrically conductive material.

4. The method of claim 3, wherein the via opening is disposed laterally between opposing sidewalls of the second CESL facing the dielectric material.

5. The method of claim 3, wherein the via opening exposes sidewalls of the second dielectric layer, wherein forming the via further comprises, before filling the via opening, lining the sidewalls of the second dielectric layer with a barrier layer.

6. The method of claim 3, wherein the via opening exposes sidewalls of the upper source/drain region and an upper surface of the lower source/drain region, wherein forming the via further comprises, before filling the via opening, forming silicide regions along the sidewalls of the upper source/drain region and along the upper surface of the lower source/drain region.

7. The method of claim 3, wherein the dummy gate structure overlies a first portion of the nanostructure, wherein the method further comprises, after forming the source/drain opening and before sequentially forming the lower source/drain region and the first dielectric structure:
replacing the second dummy material in the first portion of the nanostructure with an isolation structure; and
replacing end portions of the first dummy material exposed by the source/drain opening with inner spacers.

8. The method of claim 7, wherein replacing the end portions of the first dummy material comprises:
removing the end portions of the first dummy material exposed by the source/drain opening to form sidewall recesses in the first dummy material;
lining sidewalls and a bottom of the source/drain opening with an inner spacer layer, wherein the inner spacer layer fills the sidewall recesses; and
performing an anisotropic etching process to remove portions of the inner spacer layer disposed outside the sidewall recesses.

9. The method of claim 7, further comprising, after forming the second dielectric structure, replacing the dummy gate structure with a replacement gate structure.

10. The method of claim 9, wherein replacing the dummy gate structure comprises:
removing the dummy gate structure to form a gate trench, wherein the gate trench exposes the first portion of the nanostructure;
selectively removing the first dummy material in the first portion of the nanostructure, wherein after the selective removing, the semiconductor material in the upper nanostructure and the lower nanostructure of the first portion of the nanostructure forms upper channel regions and lower channel regions, respectively, of the semiconductor device;
forming a gate dielectric material around the upper channel regions and the lower channel regions; and
forming a gate electrode material around the gate dielectric material.

11. The method of claim 10, wherein replacing the dummy gate structure further comprises:
after forming the gate electrode material, recessing the gate electrode material below an upper surface of the isolation structure distal from the fin, wherein the recessed gate electrode material around the lower channel regions forms a lower gate electrode;
forming an isolation layer over the lower gate electrode; and
after forming the isolation layer, forming an upper gate electrode by forming the gate electrode material around the upper channel regions.

12. A method of forming a semiconductor device, the method comprising:
forming a nanostructure over a fin, wherein the nanostructure comprises:
a lower nanostructure comprising one or more layers of a first dummy material interleaved with one or more layers of a semiconductor material;
an upper nanostructure over the lower nanostructure and comprising one or more layers of the first dummy material interleaved with one or more layers of the semiconductor material; and
a second dummy material between the lower nanostructure and the upper nanostructure;
forming a dummy gate structure over the nanostructure;
forming a source/drain opening in the nanostructure adjacent to the dummy gate structure;
sequentially forming a lower source/drain region and a first dielectric structure in the source/drain opening, wherein the first dielectric structure comprises a first contact etch stop layer (CESL) that extends conformally along exterior surfaces of the lower source/drain region and comprises a first dielectric layer over the first CESL;
forming an upper source/drain region in the source/drain opening over the first dielectric structure;
forming silicide regions along exterior surfaces of the upper source/drain region;
performing an anisotropic etching process using the silicide regions as an etching mask, wherein the anisotropic etching process uses an etchant that selectively removes the first dielectric layer, wherein a first portion of the first dielectric layer under the upper source/drain region remains after the anisotropic etching processing;
after performing the anisotropic etching process, forming a second CESL that extends conformally along the silicide regions, along sidewalls of the first portion of the first dielectric layer, and along the first CESL; and
after forming the second CESL, forming a second dielectric layer in the source/drain opening around the lower source/drain region and around the first portion of the first dielectric layer.

13. The method of claim 12, wherein the upper source/drain region extends above the second dielectric layer, wherein the method further comprises forming a third dielectric layer over the second dielectric layer and around the upper source/drain region.

14. The method of claim 13, further comprising, after forming the second dielectric layer and before forming the third dielectric layer, forming a third CESL over the second CESL and around the upper source/drain region.

15. The method of claim 12, further comprising, after forming the second dielectric layer, forming a via that electrically couples the upper source/drain region and the lower source/drain region, wherein forming the via comprises:
forming a via opening that extends through the silicide regions, through the upper source/drain region, through the first portion of the first dielectric layer, through the first CESL, and into the lower source/drain region; and
filling the via opening with an electrically conductive material.

16. The method of claim 15, wherein the via opening is disposed laterally between opposing sidewalls of the second CESL facing the first portion of the first dielectric layer.

17. A semiconductor device comprising:
a substrate;
lower channel regions disposed vertically over the substrate;
upper channel regions disposed vertically over the lower channel regions;
an isolation structure between the lower channel regions and the upper channel regions;
a lower source/drain region at first ends of the lower channel regions;
an upper source/drain region at second ends of the upper channel regions;
a dielectric structure between the lower source/drain region and the upper source/drain region, wherein the dielectric structure comprises:
a first contact etch stop layer (CESL) extending conformally along exterior surfaces of the lower source/drain region;
a dielectric plug between the lower source/drain region and the upper source/drain region;
a second CESL lining sidewalls of the dielectric plug and contacting the first CESL; and
a dielectric layer contacting and extending along the first CESL and the second CESL, wherein the lower source/drain region and the dielectric plug are embedded in the dielectric layer;
a lower gate electrode around the lower channel regions; and
an upper gate electrode around the upper channel regions.

18. The semiconductor device of claim 17, further comprising a fin base protruding over the substrate, wherein the lower channel regions and the upper channel regions are disposed vertically over the fin base, wherein the second CESL further extends along a bottom surface of the dielectric plug facing the lower source/drain region.

19. The semiconductor device of claim 17, further comprising a via that extends through the upper source/drain region, through the dielectric plug, through the second CESL, through the first CESL, and into the lower source/drain region, wherein the via is disposed laterally between opposing sidewalls of the second CESL.

20. The semiconductor device of claim 19, further comprising:
a first silicide region between the via and the upper source/drain region; and
a second silicide region along an upper surface of the lower source/drain region.
